(19) United States
(12) Patent Application Publication
(10) Pub. No.: US 2025/0079415 A1
(43) Pub. Date: Mar. 6, 2025

(54) INTEGRATED CIRCUIT INCLUDING FLASH MEMORY AND CMOS LOGIC CIRCUITRY

(71) Applicant: TEXAS INSTRUMENTS INCORPORATED, Dallas, TX (US)

(72) Inventors: Giulio Albini, Draper, UT (US); Jonathan Lane, Sandy, UT (US)

(21) Appl. No.: 18/458,193

(22) Filed: Aug. 30, 2023

(51) Int. Cl. H01L 25/16; G11C 16/08; H01L 29/423; H01L 29/66; H01L 29/788; H10B 41/30

(52) U.S. Cl. CPC H01L 25/16; G11C 16/08; H10B 41/30; H10D 30/0411; H10D 30/68; H10D 30/6892

(57) ABSTRACT

An integrated circuit (IC) including Flash memory and CMOS logic circuitry and a method of fabrication thereof is disclosed. The IC comprises a substrate including a first region and a second region, where a Flash memory cell gate stack is formed in the first region, a first transistor is formed in the first region and operable at a first voltage level, the first transistor including a gate formed over a first gate oxide layer exclusive of nitridation, and one or more sets of second transistors are formed in the second region, each set operable at a corresponding second voltage level different than the first voltage level and including a corresponding second gate oxide layer having nitridation.

### FIELD OF THE DISCLOSURE

Disclosed implementations relate generally to the field of integrated circuits (ICs) and IC fabrication. More particularly, but not exclusively, the disclosed implementations relate to an IC including Flash memory and CMOS logic circuitry.

### BACKGROUND

A non-volatile memory (NVM) bitcell is an electronic element that is configured to store information. A threshold voltage can be used to discriminate between logic levels of the bitcell, such as a logic low level (“0”) or a logic high level (“1”). This stored value may sometimes be referred to as information (or a bit), which may be read by sense amplifier circuitry. Although integrating an NVM array with additional circuitry, e.g., logic circuitry, in the same IC device is a desirable goal for the semiconductor manufacturing industry, it is not without challenges as will be set forth below.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC device including Flash memory and CMOS logic circuitry fabricated on a single semiconductor die using a modularized process flow.

In one example, an IC device including Flash memory and CMOS logic circuitry is disclosed. The IC device comprises a substrate including a first region and a second region, where a Flash memory cell gate stack is formed in the first region, a first transistor is formed in the first region and operable at a first voltage level, the first transistor including a gate formed over a first gate oxide layer exclusive of nitridation, and one or more sets of second transistors are formed in the second region, each set operable at a corresponding second voltage level different than the first voltage level and including a corresponding second gate oxide layer having nitridation. In one variation, the first region may include a first recessed area and a second recessed area different than the first recessed area, where the Flash memory cell gate stack is located in the first recessed area, and the first transistor is located in the second recessed area.

In one example, a method of fabricating an IC device containing Flash memory and CMOS logic circuitry is disclosed. The method may comprise, among others, forming a Flash memory cell gate stack in a first region of a substrate, forming a first transistor operable at a first voltage level in the first region, the first transistor including a gate formed over a first gate oxide layer exclusive of nitridation, and forming one or more sets of second transistors in the second region, each set operable at a corresponding second voltage level different than the first voltage level and including a corresponding second gate oxide layer having nitridation. The method may further comprise forming a wordline (WL) transistor in the first region coupled to the Flash memory cell gate stack, the WL transistor including a WL gate formed over a third gate oxide layer exclusive of nitridation. In one implementation, the first gate oxide layer may have a thickness of about 160 Å to 200 Å. In one implementation, the second gate oxide layer may have a thickness ranging from about 15 Å to about 45 Å based on the corresponding second voltage level. In one implementation, the third gate oxide layer may have a thickness of about 15 Å to 35 Å. In one implementation, the Flash memory cell gate stack, the WL transistor and associated common erase gate (EG) as well as the first transistor are formed in the first region before forming the one or more sets of second transistors in the second region.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1 depicts a block diagram of an integrated circuit (IC) including Flash memory and CMOS logic circuitry according to some examples of the present disclosure;

FIG. 2A depicts a cross-sectional view of a pair of Flash memory bitcells that may be fabricated in a modularized process flow for fabricating an IC including Flash memory, CMOS logic circuitry, or both, in accordance with some examples of the present disclosure;

FIG. 2B depicts a schematic representation of the pair of Flash memory bitcells depicted in FIG. 2A;

FIGS. 3A and 3B are flowcharts of an IC fabrication method according to some examples of the present disclosure;

FIGS. 4A-4Y depict cross-sectional views of various stages of a process flow for fabricating an IC having Flash memory, CMOS logic circuitry, or both, in a modularized flow according to some examples of the present disclosure; and

FIG. 5 depicts a cross-sectional view of an IC where various circuit portions may be formed in a substrate including one or more recessed areas and one or more non-recessed areas using a modularized flow according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of an IC including Flash memory and CMOS logic circuitry and a method of manufacturing the same in a modularized process flow will be set forth below in the context of a Flash memory cell architecture based on a split-gate architecture.

Flash memory is a non-volatile storage medium that may store information in an array of memory cells, also referred to as bitcells. This stored information (or “bits”) can be electrically erased, programmed, and read. In some cases, an array of floating-gate transistor bitcells may be used in creating a Flash memory circuit or device. A floating-gate transistor bitcell resembles a standard metal-oxide-field-effect-transistor (MOSFET) except that the floating-gate transistor bitcell includes multiple gates (e.g., a control gate overlying an electrically isolated floating gate). An electrical state of a bitcell can be used to define a logic level such as a logic low level (e.g., a digital low or “0”) or a logic high level (e.g., digital high or “1”) depending on the Boolean logic used by a sense circuit for reading the data in a read operation. This defined logic level may sometimes be referred to as information (or a bit) stored in the bitcell.

Storage of information may be effectuated using changes in the floating gate characteristics of the bitcells. The threshold voltage (V_{T}) of a floating-gate type transistor bitcell may change because of the presence or absence of a charge trapped in its floating gate due to electrical isolation. The trapped charge alters the threshold voltage (relative to the unchanged threshold voltage) of the floating-gate transistor bitcell. For instance, in an example NMOS-based Flash implementation, the threshold voltage is increased when electrons are trapped in the floating gate of the bitcell (e.g., a “programmed” bitcell). On the other hand, the threshold voltage is decreased when electrons are depleted in the floating gate of an NMOS bitcell (e.g., an “erased” bitcell). Accordingly, when a voltage is applied to the control gate of a bitcell of an NMOS-based Flash memory array during the read operation, the bitcell is conductive in an erased state and nonconductive in a programmed state, where each state is operative for generating a corresponding read current (I_{READ}) that is provided to a sense amplifier for sensing the data. In an example arrangement, the sense amplifier may be configured to determine the data relative to another current, referred to as a reference current (IREF). In PMOS-based Flash implementation, these relationships are opposite, in that the PMOS bitcells are conductive in programmed state and non-conducting in erased state. In general, regardless of whether PMOS-based or NMOS-based NVM is implemented, a read current generated when the bitcell is conducting may be referred to as “ON” read current (I_{ON}), indicating a logic level of a first type. Similarly, a read current generated when the bitcell is non-conducting may be referred to as “OFF” read current (I_{OFF}) that is indicative of a logic level of a second type complementary to the first type.

In some implementations, floating-gate transistor bitcells may utilize a split-gate architecture to store bits, where a split-gate Flash bitcell may include more than one transistor. For example, a split-gate Flash memory bitcell may have a gate portion (referred to as a wordline gate) adjacent to the control gate that is disposed over the floating gate, such that the channel of the memory bitcell is controlled by the wordline gate as well as the floating gate. This arrangement causes the split-gate Flash memory bitcell to act as two transistors operating in series, equivalent to 1.5 transistors (1.5T) per cell in some implementations, where two Flash bitcells may share a source or a drain (depending on NMOS or PMOS implementation). Similarly, in some configurations, the split-gate Flash bitcell can have a 2T configuration based on two transistors. In general operation, a combination of one or more of the gates of a split-gate bitcell can be configured to program, erase, and/or read the bitcell.

Embedded Flash memory (eFlash) (e.g., one or more Flash bitcell arrays integrated with other circuitry such as CMOS logic circuitry on a single semiconductor die) is a key enabling technology for many programmable semiconductor products requiring small form factor and low-power processing. For example, microcontrollers use eFlash to store program instructions (code) as well as data on which processing is performed using logic circuitry configured as a central processing unit (CPU) core. Many Internet-of-Things (IoT) devices use eFlash to enable smart, flexible, and secure products that can be updated wirelessly, or over-the-air (OTA). Further, electronic devices with eFlash may be configured to enable a wide range of products from smart cards and wearables to factory automation systems and autonomous vehicles, to mention a few.

Although the integration of non-volatile Flash memory (and/or other types of NVM) with CMOS logic circuity is highly desirable, fabricating Flash memory and CMOS logic using an integrated technology platform remains challenging because of, among others, the need to satisfy the requirements and technical specifications of multiple products having different functionalities running on the same process flow. In certain process flows where CMOS logic and Flash memory portions are fabricated substantially concurrently or in parallel, the fabrication of high voltage (HV) transistors required for Flash memory operations is integrated with the fabrication of transistors used in CMOS logic circuits that may be configured to operate at different voltages, e.g., at voltages lower than the voltage levels required for operating the HV transistors used in Flash memory. In such scenarios, manufacture of different products using the same process flow, e.g., some products having both Flash memory and CMOS logic circuitry while others having either Flash memory only or CMOS logic circuitry only, can be beset with technical issues as well as economic concerns. For example, in order to manufacture a CMOS-only product, additional process stages that simulate the presence of Flash memory and HV circuitry may be required so as to avoid potential performance mismatch in the CMOS transistors, which can add to the cost of manufacture as well as detrimentally affect overall die yields, especially in advanced technology nodes that continue to scale to smaller geometries.

Examples of the present disclosure recognize the foregoing challenges and accordingly provide a technical solution for fabricating Flash memory, associated HV devices and CMOS logic circuitry in an integrated process flow that may be implemented in a modularized manner what may be decoupled in different deployment scenarios. In examples herein, Flash memory cells and HV devices may be processed and substantially completed as part of a modularizable initial phase of a “Flash First” flow that may be implemented independent from a subsequent phase, or “module”, of the flow dedicated to forming CMOS logic circuitry having transistor devices operable at voltage levels different from the HV devices, as will be set forth in detail further below.

Whereas various examples of the present disclosure may be beneficially applied to manufacturing electronic devices including embedded Flash memory based on the split-gate architecture, the teachings herein are not limited thereto and may be practiced in the manufacture of any NVM (e.g., Flash memory based on architectures other than the split-gate architecture) integrated with a broad range of CMOS logic circuits as well as other memory such as DRAM, SRAM, etc., in a single semiconductor die. While such examples and variations may be expected to reduce manufacturing defects that could otherwise reduce yields, reliability or electrical performance, no particular result is a requirement of the present disclosure unless explicitly recited in a particular claim.

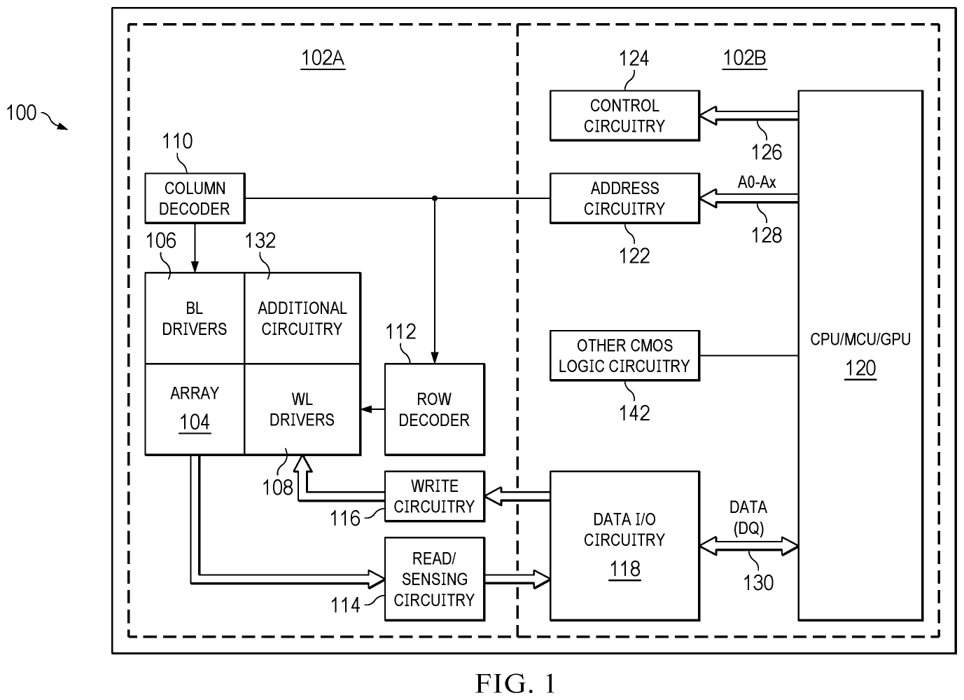

Referring now to FIG. 1, depicted therein is a block diagram of an integrated circuit (IC) including Flash memory and CMOS logic circuitry that may be fabricated in a modularized flow according to some examples of the present disclosure. In one arrangement, IC 100 is illustrative of an electronic device fabricated on any suitable semiconductor substrate, where one or more Flash memory arrays, e.g., array 104, and associated high voltage circuitry may be formed in one or more areas or regions, e.g., a first region 102A, and one or more remaining circuit portions of IC 100 including circuitry operable at lower voltages may be formed in one or more areas, e.g., a second region 102B, separate from the first region 102A of the semiconductor substrate. Depending on the level of integration and/or functional implementation, high voltage circuitry associated with the Flash memory array 104 may include circuitry comprising at least portions of one or more of column decoders 110, row decoders 112, bitline drivers 106, wordline drivers 108, write circuitry 116, and read/sensing circuitry 114. In some examples, at least portions of the foregoing components, which may be generally referred to as peripheral circuits, may be formed of transistors disposed in high voltage (HV) domains operable at suitable voltages, e.g., 4.0V, 5.0V, or higher, configured to facilitate Flash memory operations, e.g., read, erase and program operations.

In some examples, the remaining circuit portions of IC 100 may include various types of electronic circuitry such as, without limitation, field-programmable gate array (FPGA) circuitry, graphics processing unit (GPU) circuitry, digital signal processor (DSP) circuitry, system-on-chip (SoC) circuitry, microprocessor (MPU) circuitry, microcontroller (MCU) circuitry, application-specific integrated circuit (ASIC) circuitry, programmable array logic (PAL) circuitry, generic array logic (GAL) circuitry, programmable logic device (PLD) circuitry, mixed-signal circuitry, analog circuitry, transducer circuitry, microelectromechanical systems (MEMS) circuitry, sense amplifier circuitry, data input/output (I/O) circuitry, neural processing unit (NPU) circuitry, artificial intelligence (AI) processing unit (AIPU) circuitry, volatile memory circuitry, macrocell array (MCA) circuitry, and programmable logic array (PLA) circuitry, and the like. Depending on implementation, one or more foregoing components of the remaining circuit portions may be broadly defined as “CMOS logic circuitry” comprising a plurality of transistors disposed in one or more voltage domains including low voltage (LV) domains operable at, e.g., 1.0V, 1.5V, 1.8V, 3.3V, etc., without limitation. For purposes of the present disclosure, a description of IC 100 will be set forth below as a representative example of an electronic device including an embedded Flash memory array, e.g., array 104, integrated with a plurality of circuits illustrative of CMOS logic circuitry and other circuitry, where the Flash memory cells may be fabricated along with associated HV devices in a modularized flow according to the examples herein.

In some arrangements, Flash memory array 104 may comprise a plurality of Flash memory cells based on a split-gate cell architecture, which may be formed in the first region 102A along with one or more HV devices in a first phase of the modularized flow as will be discussed in further detail below. On the other hand, various types of CMOS logic circuitry including transistors operable at lower operational voltages may be fabricated in the second region 102B according to a subsequent phase of the flow (e.g., a second phase) following the first phase. In some examples, the first region 102A includes one or more recessed areas (e.g., in comparison to the second region 102B), in which the Flash memory array 104 and the one or more HV devices are located. As the fabrication of HV devices associated with Flash memory is decoupled from—and precedes—the fabrication of LV domain transistors forming the CMOS logic circuitry, potential issues arising from having to match transistor performance across a range of voltages, which may be prevalent in certain process flows involving processing of Flash bitcells and CMOS logic in a staggered parallel fashion, e.g., going back and forth between Flash processing and CMOS logic processing until both circuit portions are completed substantially simultaneously, may be advantageously mitigated. Further, because the HV devices are fabricated along with the Flash memory cells, the process flow may be implemented in a modularized fashion in that the same process flow may be configured to fabricate Flash-only devices (e.g., a standalone application), CMOS-only devices (e.g., an IC without embedded Flash memory), or IC devices containing both Flash memory and CMOS logic circuitry having LV devices (e.g., in an embedded application).

Whereas a single Flash memory array and associated HV domain circuitry is shown in FIG. 1 for simplicity, some examples of the IC device 100 may include multiple arrays, each having a respective set of memory cells arranged in corresponding rows (e.g., wordlines) and columns (e.g., bitlines) as well as corresponding HV circuit portions. Depending on implementation, appropriate wordline driving circuitry 108 and bitline driving circuitry 106 may be operably coupled to the Flash memory array 104. Additional circuitry 132, which may drive lines of the Flash memory array 104 other than bitlines and wordlines may also be operatively associated with the Flash memory array 104 in some examples. In general, Flash memory cells (also referred to as bitcells in some examples) arranged in the same row share a common wordline, and each wordline may be driven by a wordline driver in wordline driving circuitry 108. Likewise, Flash memory cells arranged in the same column share a common bitline, and each bitline may be driven by a bitline driver in bitline driving circuitry 106.

In some examples, the IC device 100 may include suitable processing circuitry 120, which may be configured to control the general operation of the device 100. Depending on implementation, processing circuity 120 may provide the processing capability to execute an operating system, programs, user and application interfaces, and any other functions of the device 100. Accordingly, the processing circuitry 102 may include a general-purpose or application-specific (ASIC) processor based upon any known or heretofore unknown CPU architectures, FPGA circuitry, GPU/DSP circuitry, embedded MCU/MPU circuitry, and/or related circuitry, as previously noted.

By way of example, instructions or data to be processed by the processing circuitry 120 may be stored in the Flash memory array 104. Depending on application, the Flash memory array 104 may be configured to store a variety of information used for various purposes. For instance, the Flash memory array 104 may store firmware, such as a basic input/output system (BIOS), an operating system, various programs, applications, or any other routines that may be executed on or by the IC device 100, such as user interface functions, processor functions, and so forth. In general operation, the processing circuitry 120 may issue suitable read or write commands to retrieve data from or write data to array 104, respectively.

In some examples, the IC device 100 may include address buffer circuitry 122, which may be configured to latch address signals provided on an address bus 128 coupled to the processing circuitry 120. Address signals may be received and decoded by a row decoder 112 and a column decoder 110 to access one or more particular locations of the Flash memory array 104. For example, a wordline may be selected based upon a portion of an address value that identifies a row of the array 104, and a bitline may be selected based upon a portion of the address value that identifies a column of the array 104. The number of address input connections provided as address bus 128 depends upon the density and architecture of the Flash memory array 104. Further, appropriate sense amplifier circuitry 114 and write circuitry 116 may be provided in conjunction with data input/output (I/O) circuitry 118 for facilitating read/write operations with respect to the Flash memory array 104, where data to be stored or retrieved may be provided via a data bus 130.

In some examples, the IC device 100 may include command control circuitry 124 operable to decode command signals provided from the processing circuitry 120 by way of a control bus 126, where appropriate command signals may be provided to control the operations relative to the Flash memory array 104. For instance, the command signals may include read, program, and erase commands for reading data from, write data to, or selectively erase bitcells of the Flash memory array 104. In still further examples, various other types of CMOS logic circuitry 142 operating in different voltage domains may be provided as part of the IC device 100, which may be fabricated in the second region 102B of the semiconductor substrate along with the other circuit portions of the device 100 set forth above.

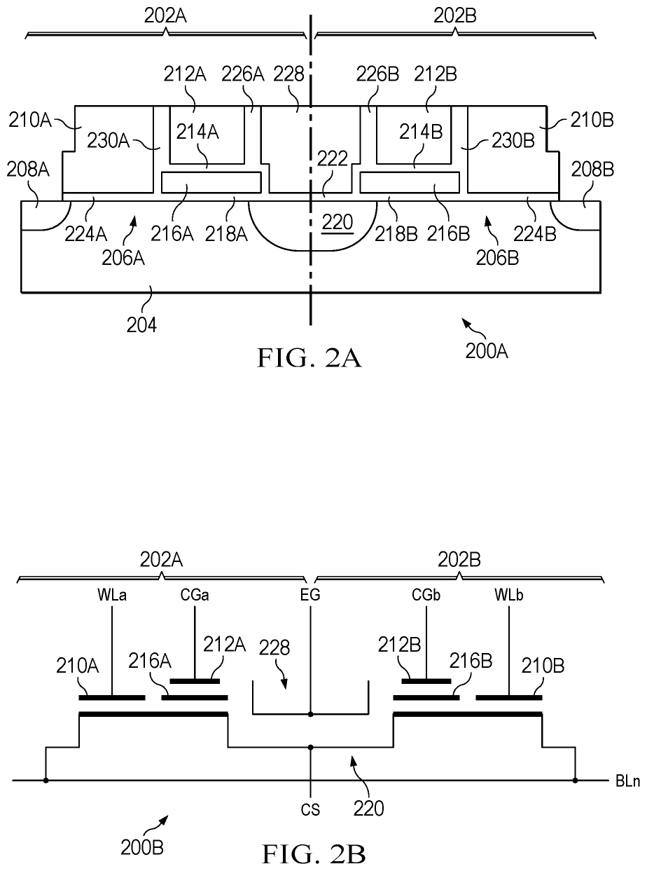

FIG. 2A depicts a cross-sectional view of a pair of adjacent Flash memory cells that may be fabricated according to some examples of the present disclosure. FIG. 2B depicts a schematic representation of the Flash memory cells depicted in FIG. 2A. The pair of Flash memory cells depicted in FIGS. 2A and 2B are examples of or include aspects of Flash memory cells based on a split-gate cell architecture. As depicted in FIGS. 2A and 2B, the Flash memory cells include a control gate (CG), a wordline (WL), a floating gate (FG), and an erase gate (EG), where a common source (CS) terminal may be shared between two adjacent bitcells that each have a drain coupled to a bitline. Taking FIGS. 2A and 2B together, a description of the structure and general operation of example Flash memory cells is set forth below.

In an example arrangement, memory cell pair 200 comprises a first memory cell 202A and a second memory cell 202B coupled together to a same bitline BLn and may form adjacent memory cells in a column of a Flash memory array, e.g., array 104 shown in FIG. 1. Memory cells 202A and 202B may include a substrate 204, which may include a portion of area 102A, of a semiconductor die formed in a semiconductor wafer (not specifically shown). In some examples, substrate 204 may comprise a semiconductor material of a first conductivity type, such as p-type. Because memory cells 202A and 202B have an identical structure, a description of memory cell 202A is provided herein in detail, which is equally applicable to memory cell 202B. With respect to the memory cell 202A, substrate 204 includes a first region 220 and a second region 208A, both of which are of a second conductivity type, such as n-type. The first region 220 may represent a source region and the second region 208A may represent a drain region, which may be connected to the bitline BLn. The source region 220 may be shared by the memory cells 202A, 202B, which may be connected to a common source line CS. A channel region 206A may be disposed between the first region 220 and the second region 208A, which provides for conduction of charges therebetween.

A wordline WLa forms or is otherwise connected to a select gate 210A formed over a first portion of the channel region 206A, (e.g., a portion immediately abutting the second region 208A) and insulated therefrom by a gate oxide 224A disposed between the select gate 210A and the substrate 204. Depending on implementation, the select gate 210A (also referred to as a wordline gate) may extend over a portion of the second region 208A, and may be configured to operate as a wordline transistor (also referred to as an access transistor) with respect to the memory cell 202A. A floating gate (FG) 216A is positioned over a second portion of the channel region 206A, where the floating gate 216A is laterally spaced from and disposed adjacent to the select gate 210A. The floating gate 216A is insulated from the substrate 204 by a gate oxide 218A, and may extend over a portion of the first region 220.

A control gate (CG) 212A, also referred to as a coupling gate, is disposed over the floating gate 216A and is insulated therefrom by an oxide layer 214A, thereby forming a gate stack of the memory cell 202A. For purposes of some examples of the present disclosure, a Flash memory cell or bitcell, may include a wordline gate or transistor coupled to a gate stack or a storage stack in a split-gate architecture. The control gate 212A is also positioned between the select gate 210A and an erase gate 228, and is coupled to a control gate line CGa as shown in FIG. 2B. A vertical spacer 230A, which may comprise one or more dielectric layers, insulates the select gate 210A from the control gate 212A and the floating gate 216A. The erase gate 228 is disposed over the first region 220 of the substrate 204 and is insulated therefrom by a gate oxide layer 222. The erase gate 228 is also arranged adjacent to the floating gate 216A and the control gate 212A, and is insulated therefrom by another vertical spacer 226A that may include one or more suitable dielectric layers. As depicted in FIGS. 2A and 2B, the erase gate 228 is connected to a common erase gate (EG) line shared by the memory cells 202A and 202B.

The adjacent memory cell 202B shown in FIGS. 2A and 2B has a structure identical to the memory cell 202A, as noted previously, and forms a mirror image thereof with respect to the vertical dashed line separating the two memory cells 202A, 202B and passing through the shared erase gate 228 and source region 220, as depicted in FIG. 2A. Like components in the adjacent memory cell 202B are denoted with the same reference number or initialism as corresponding components in the memory cell 202A, but with a “b” or “B” appended thereto instead of an “a” or ‘A”, as applicable. For example, component 216B is a floating gate for the memory cell 202B, whereas like component 216A is the floating gate for memory cell 202A, where components 216A and 212A form a gate stack of the memory cell 202A, and components 216B and 212B form a gate stack of the memory cell 202B. In some examples, the control gates 212A, 212B of memory cells 202A, 202B, respectively, may be configured to share a common control gate driver. For example, although FIG. 2B shows separate control gate lines CGa and CGb connected to control gates 212A, 212B, respectively, the control gate lines CGa and CGb may be driven by the same control gate driver (not specifically shown in the Figures).

The structure of the transistors shown in FIGS. 2A and 2B of each of the memory cells 202A and 202B provides for a separate select gate and control gate as an example of the split-gate architecture according to some examples herein. Whereas the components described in FIG. 2A for providing insulation between the various depicted structures of the memory cells 202A and 202B, such as, elements 224A/B, 218A/B, 214A/B, 222, etc., are referred to as “oxides,” which may be formed using any suitable dielectric material, such as an oxide, a nitride, or a combination of an oxide and nitride, and may comprise one or more layers or sublayers of varying thicknesses. By way of illustration, the inter-gate dielectric layer 214A/B providing insulation between the control gate 212A/212B and corresponding floating gate 216A/216B may be formed from an oxide-nitride-oxide (ONO) layer in an example Flash First fabrication flow for forming the memory cells 202A/202B in a first region of a semiconductor substrate, as will be set forth in detail further below. Further, WL select gates 210A/210B may be formed along with one or more HV gates (not shown in FIGS. 2A/2B) in the first region of the semiconductor substrate as part of the “Flash First” fabrication flow according to examples herein.

In general operation, the memory cells 202A and 202B may be operated upon in response to commands received by suitable control circuitry of an IC device, e.g., control circuitry 124 of IC device 100, shown in FIG. 1. When either or both memory cells 202A and/or 202B are selected in response to a command, depending on whether the command indicates a read, program, or erase operation, appropriate voltages corresponding to the indicated operation may be applied to the select gate 210A/B, control gate 212A/B, erase gate 228, and source region 220 of the selected memory cell(s). A selected memory cell may refer to one identified (e.g., by an address) along with a received command, whereas an unselected memory cell is one not so identified.

By way of illustration, when memory cell 202A is selected to be erased, an erase voltage may be applied to the erase gate 228 and the other terminals of the selected memory cell 202A may be suitably biased, e.g., by applying 0V to the source 220, WL/select gate 210A, control gate 212A, and drain 208A (coupled to bitline BLn). Such biasing results in electrons tunneling from the floating gate 216A into the erase gate 228 (via Fowler-Nordheim tunneling), which causes the floating gate 216A to become positively charged, thereby lowering the cell threshold voltage. In an erased state, a read operation with respect to the selected memory cell 202A therefore results in a current flow in the channel region 206A between the drain 208A and source 220, thus indicating a logic 1. By way of example only, an erase voltage applied to the erase gate 228 during an erase operation may be a relatively high voltage, such as between approximately 8V and 14V. For instance, the erase voltage may be approximately 11V, 12V, or 13V in certain implementations.

When memory cell 202A is selected to be programmed, suitable voltages may be applied to program the memory cell 202A. For example, a relatively high voltage is applied to the control gate 212A, with lesser voltages applied to the erase gate 228, the source 220, and WL/select gate 210A (coupled to wordline WLa). A relatively small programming current may be applied to the bitline BLn, which will cause the bitline BLn to bias at a voltage. For instance, the voltage to which BLn biases may be equal to the voltage on the wordline (WLa) less the threshold voltage of the select gate 210A when the bitline BLn acts as the source. This results in a portion of the electrons in the channel region 216A that flow across the gap between the select gate 210A and the floating gate 216A acquiring enough energy to inject into the floating gate 216A via a mechanism referred to hot carrier injection. As a result, the floating gate 216A becomes negatively charged, thereby increasing the cell threshold voltage, so that a read operation results in no current flow in the channel region 206A, which may be sensed as a logic 0. By way of example only, in a program operation, a voltage of between approximately 8V and 12V may be applied to the control gate 212A, a voltage of between approximately 4V and 5V may be applied to both the source 220 and the erase gate 228, and a voltage of between approximately 0.8V and 1.3V may be applied to the select gate 210A. For instance, programming the memory cell 202A in some examples may involve applying approximately 10.5V to the control gate 212A, 4.5V to each of the source 220 and the erase gate 228, and 1V to 1.1V to the select gate 210A. A programming current applied to the bitline BLn may be between approximately 1 μA and 3 μA, which may result in the bitline BLn biasing to a voltage of approximately 0.3V.

When memory cell 202A is selected for a read operation, suitable voltages may be applied to read a data state from the memory cell 202A. In one example, 0V may be applied to the erase gate 228 and the source 220, a voltage of between approximately 2.7V and 3.3V (e.g., approximately 3.0V) may be applied to the select gate 210A, a voltage of between approximately 1.5V and 2.0V (e.g., approximately 1.8V) may be applied to the control gate 212A, and a voltage of between approximately 1.0V and 1.5V (e.g., approximately 1.2V) may be applied to the drain 208A (via bitline BLn). Depending on the amount of charge in the floating gate 216A at the time of the read operation, current will either flow (indicating a data state of 1) or not flow (indicating a data state of 0) in the channel region 206A in response to the control gate voltage. In an erased state, the absence of trapped electrons on the floating gate 216A allows for current to flow in the channel region 206A in response to applying the control gate voltage. In a programmed state, the floating gate 216A may be negatively charged due to the presence of trapped electrons, which effectively increases threshold voltage by shielding the channel region 206A from the control gate 212A, thus impeding current flow in the channel region 206A, which is indicated as a logic 0 as previously noted.

Though not shown specifically in FIG. 1, an example IC device 100 may include various driver circuits for the control gates (e.g., driving the CG lines), for the source terminals (e.g., driving the CS lines) and the erase gates (e.g., driving the EG lines) associated with a Flash memory array, e.g., array 104, comprising a plurality of bitcells 202A/202B described in detail above. Although control gates 212A and 212B are shown as physically separate structures in FIG. 2A, they may be driven by a common control gate driver circuit fabricated using suitable HV devices. In further examples, a common control gate driver may be shared by more than two cells in a given column of the array, such as by four, eight, or even sixteen or more cells. In some implementations, sharing of control gate driver circuits as well as other HV domain peripheral circuits among multiple cells can serve to reduce HV circuitry area, and thus reduce overall device size and manufacturing costs.

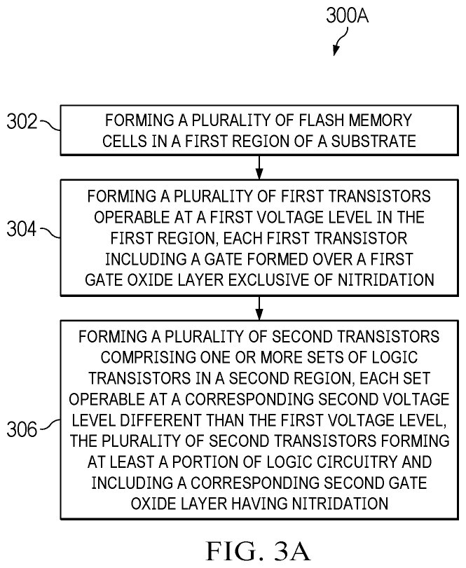

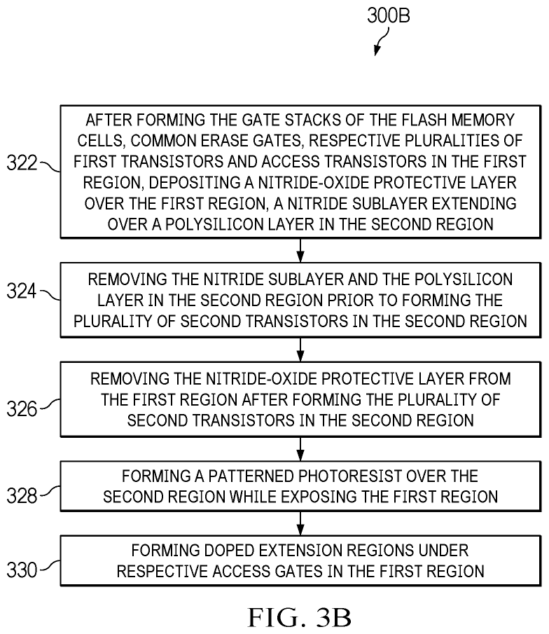

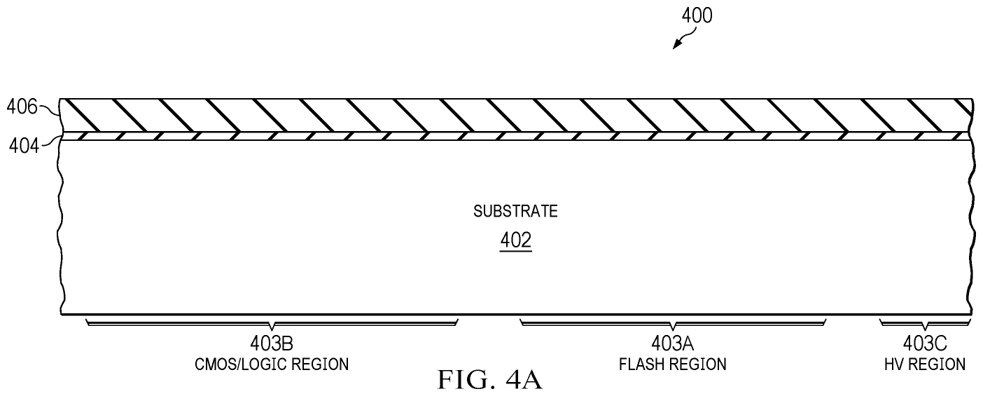

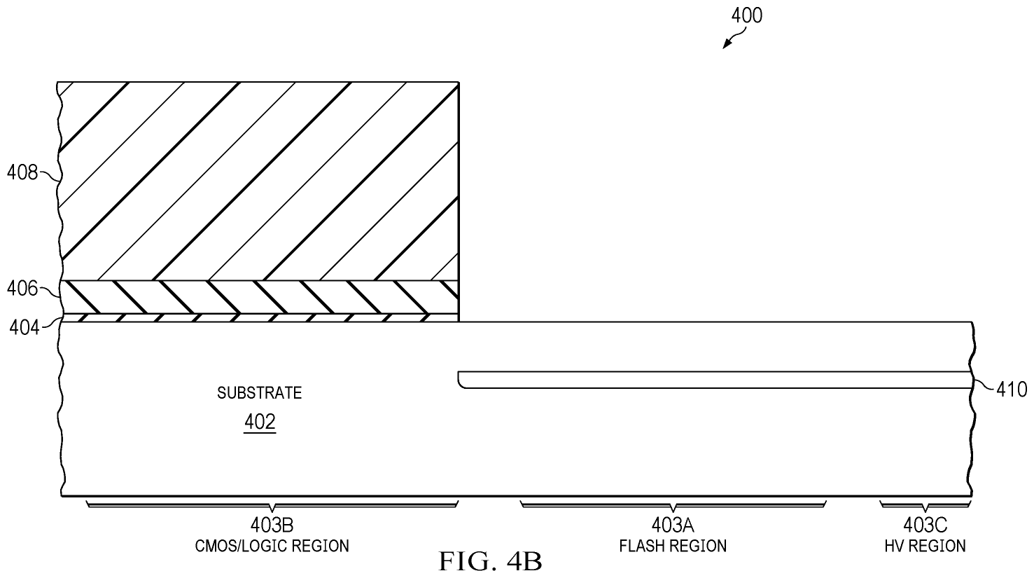

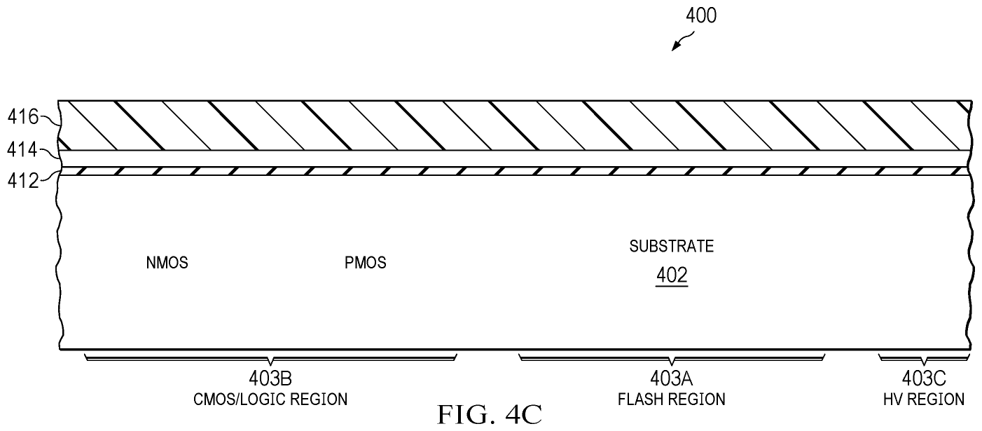

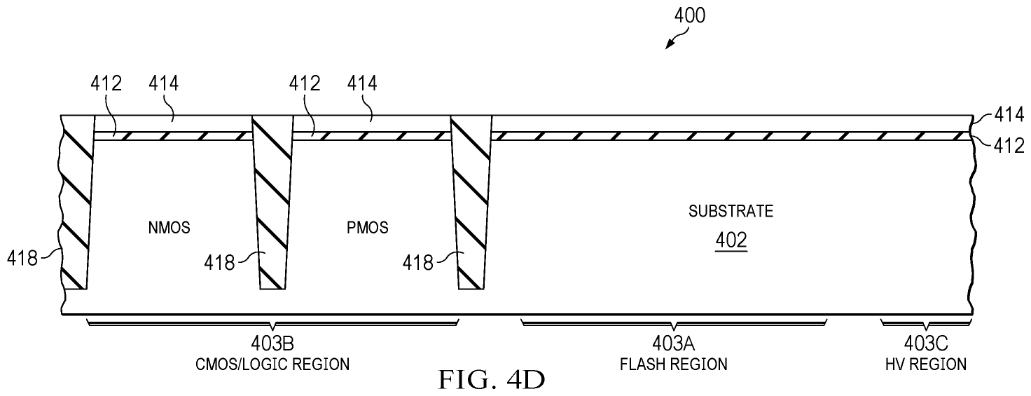

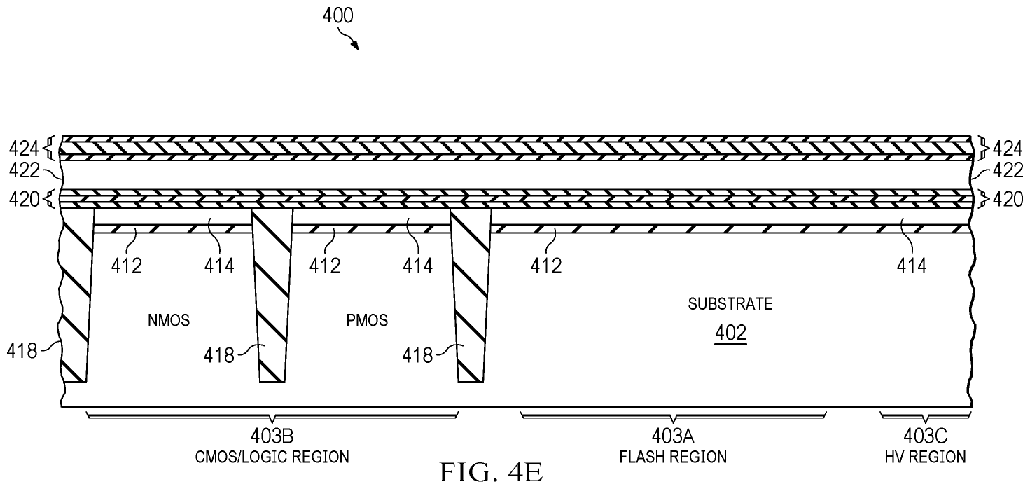

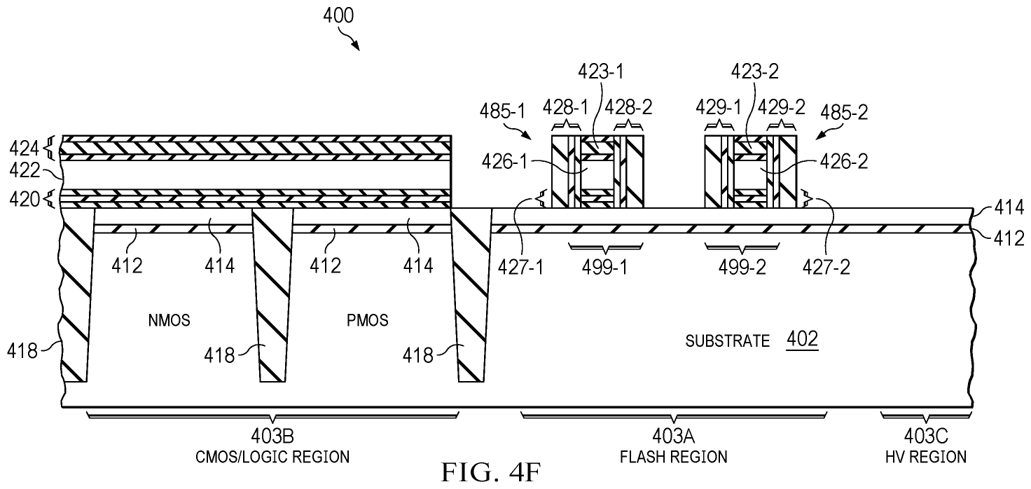

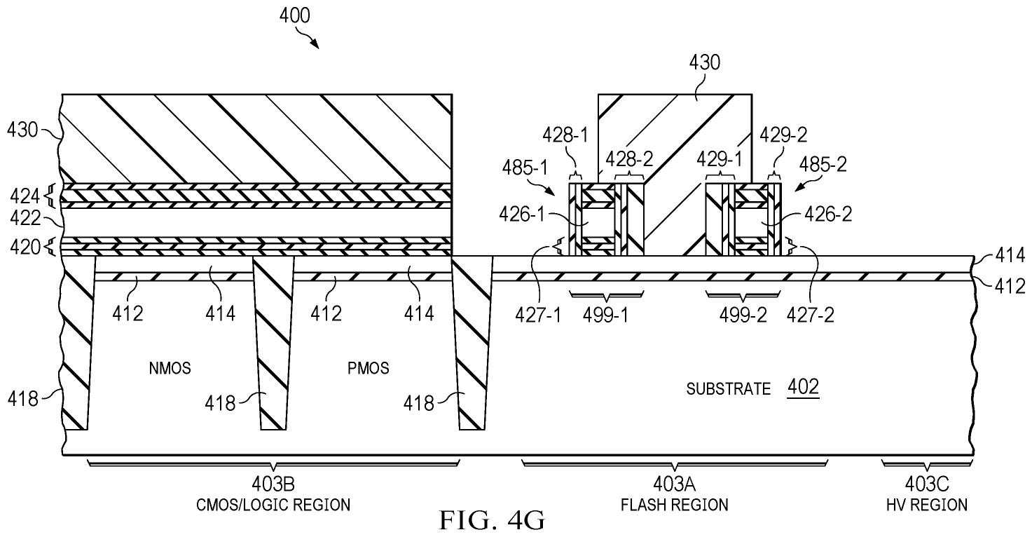

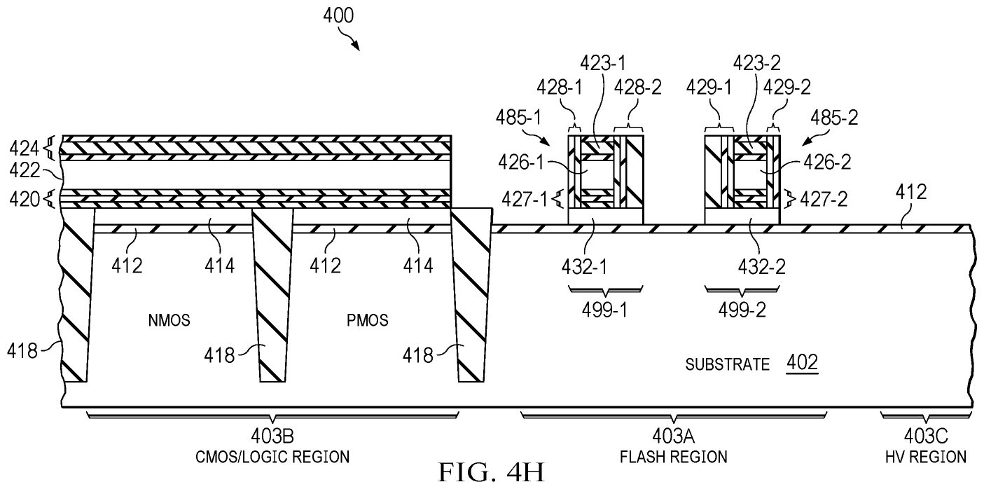

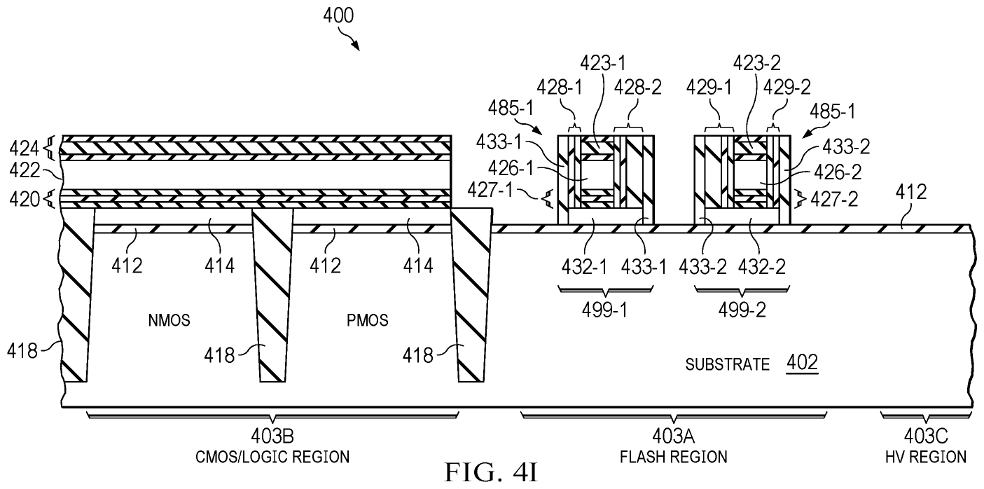

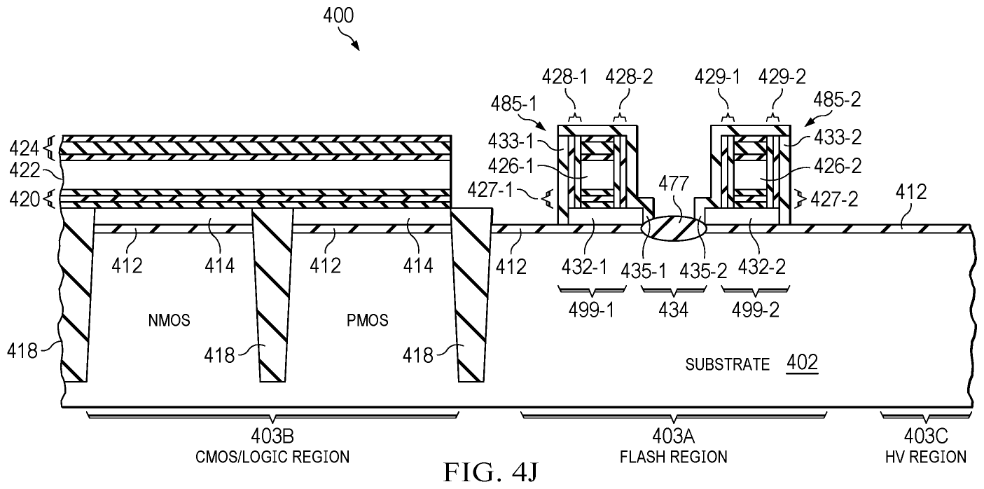

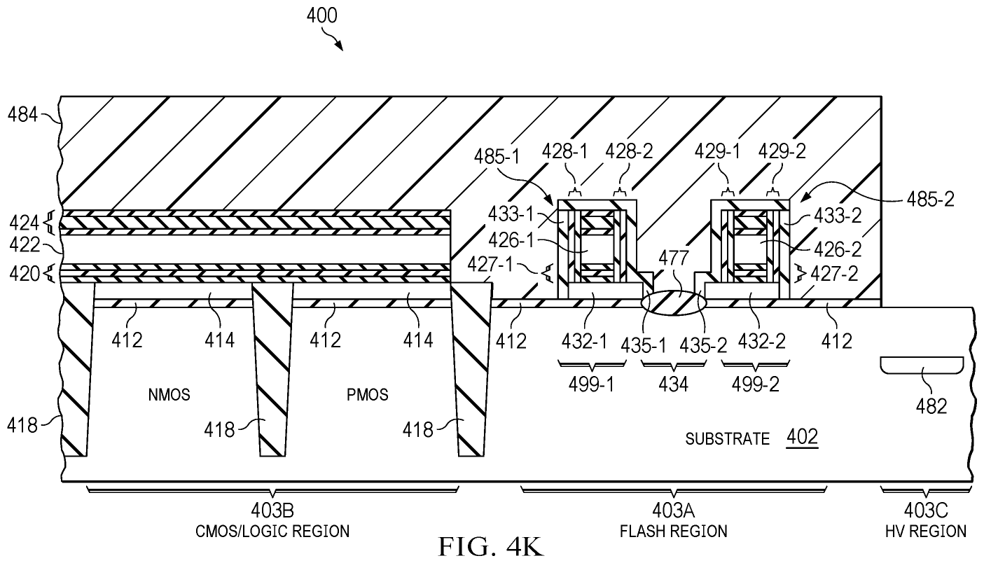

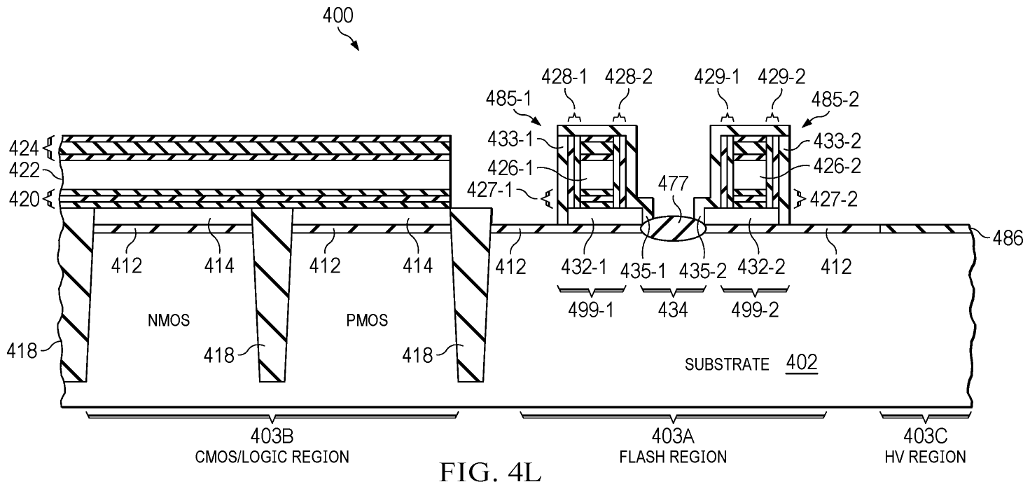

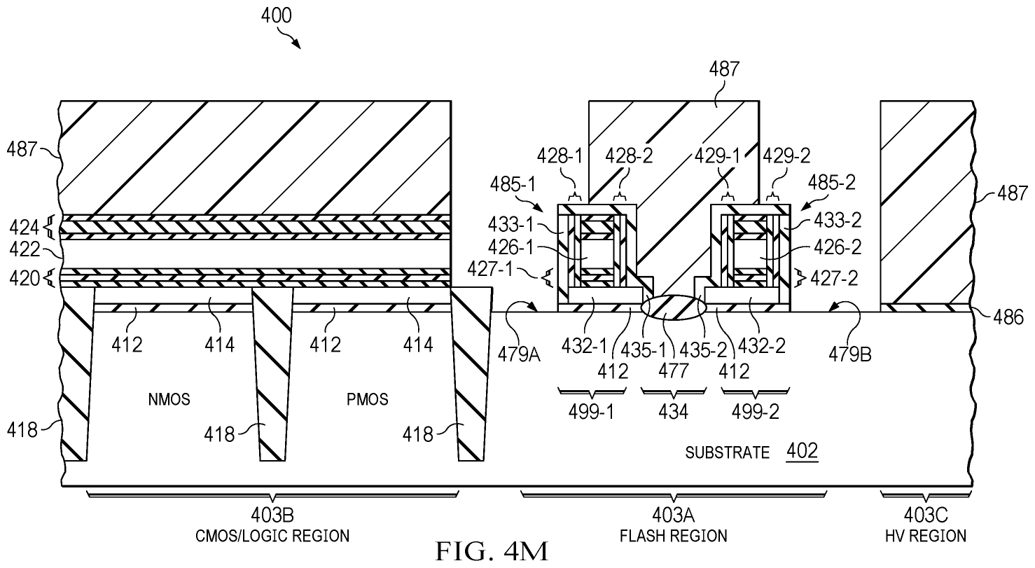

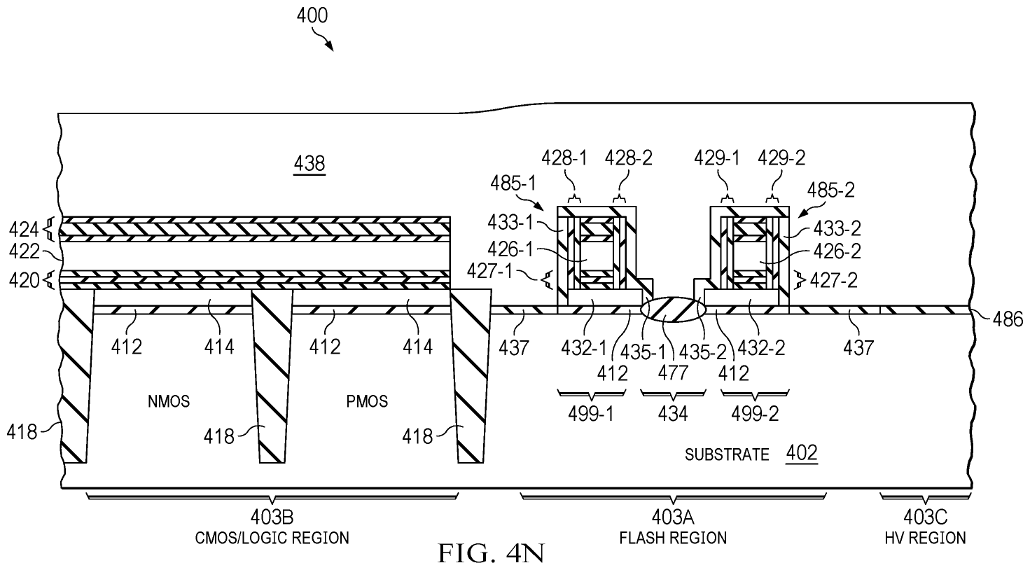

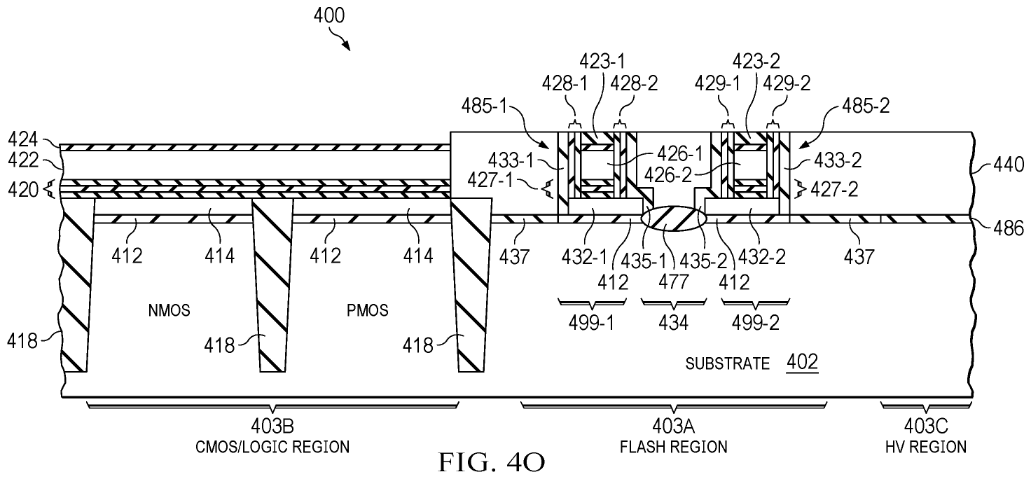

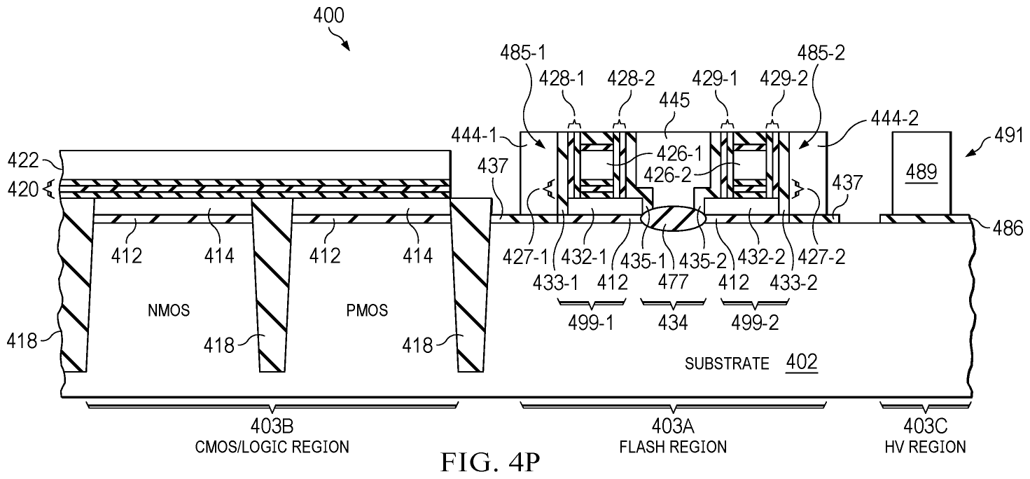

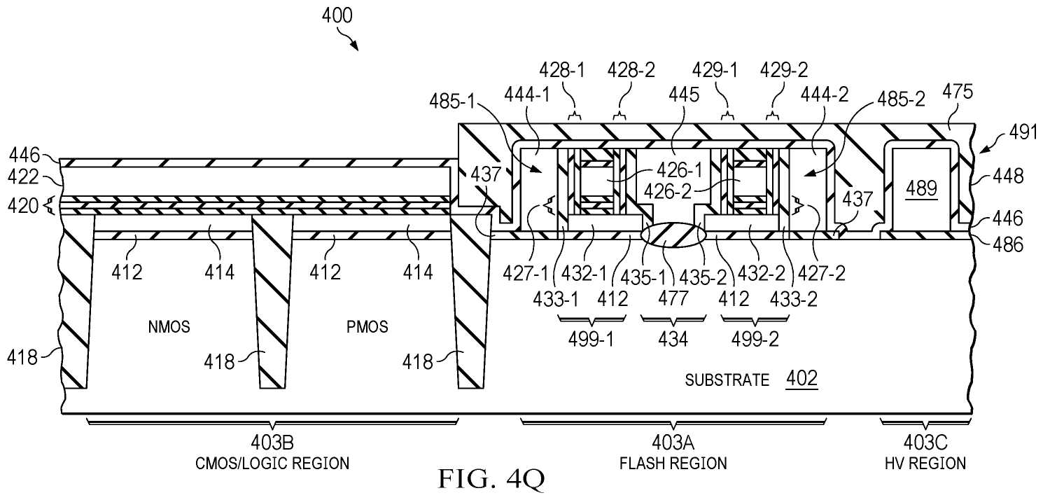

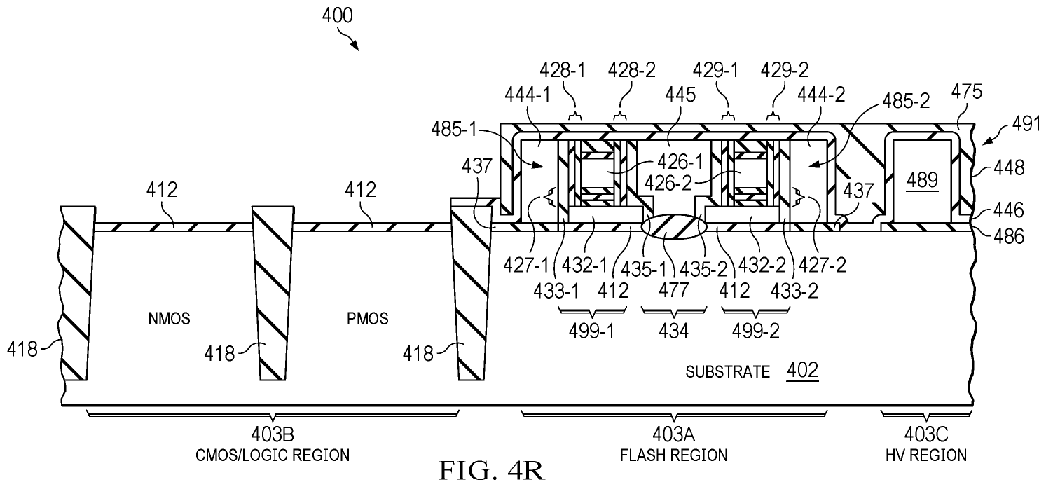

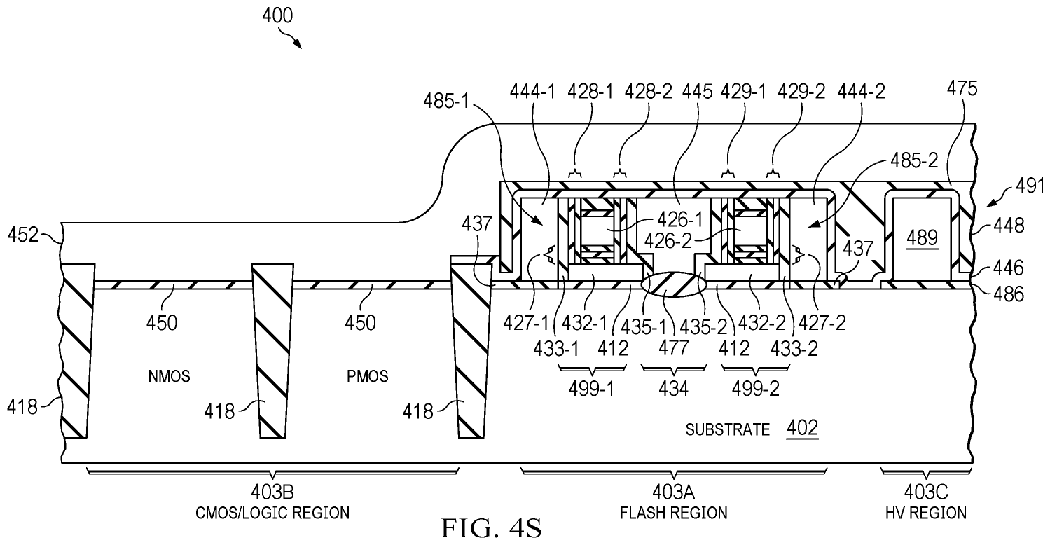

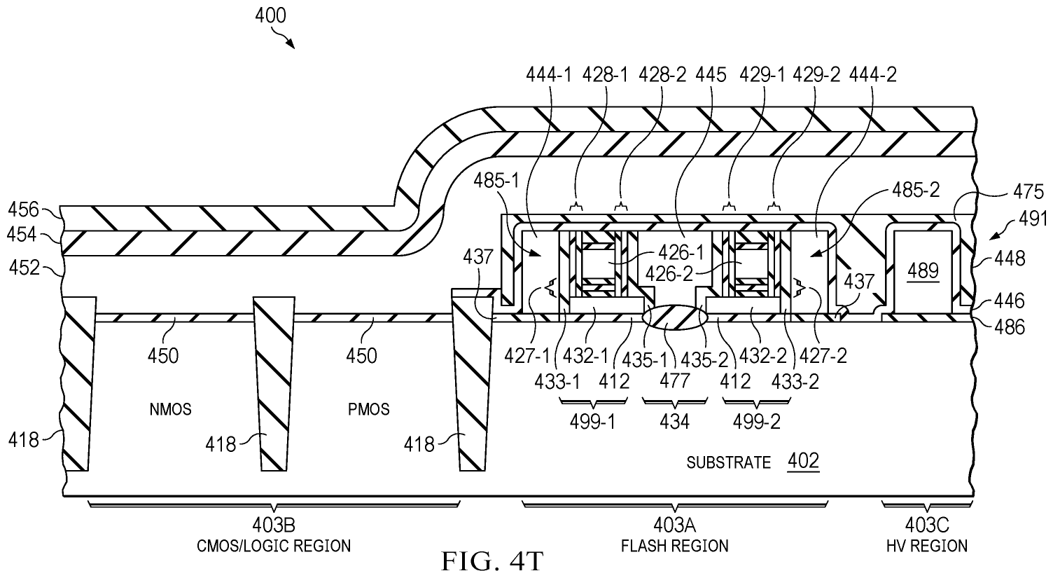

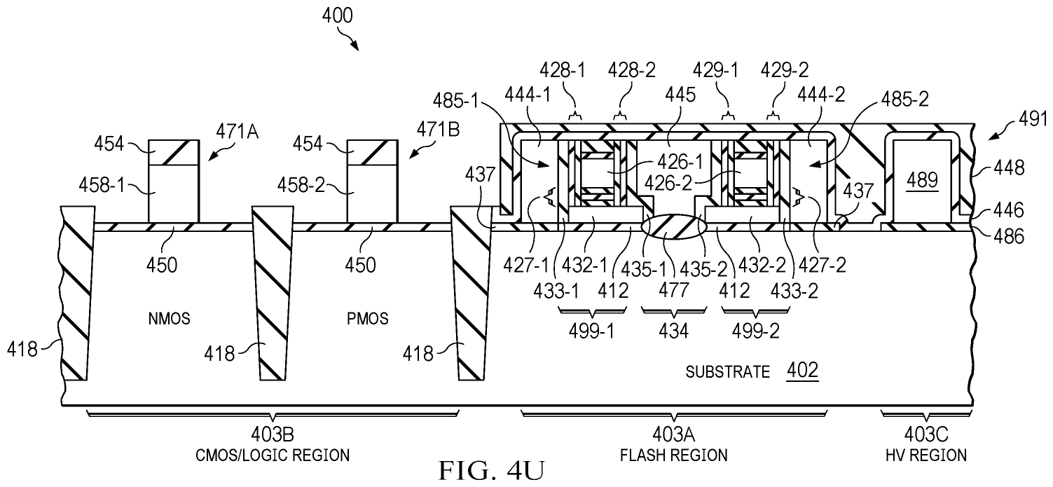

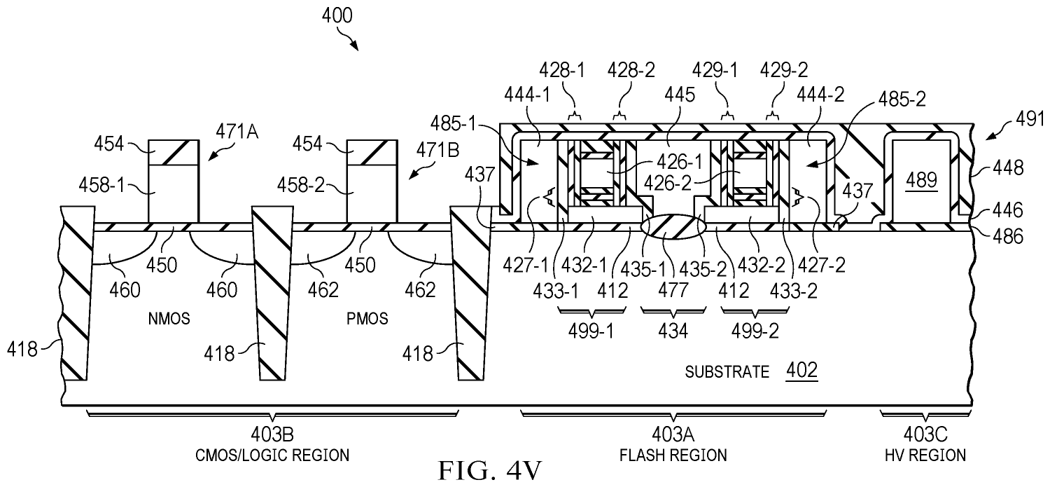

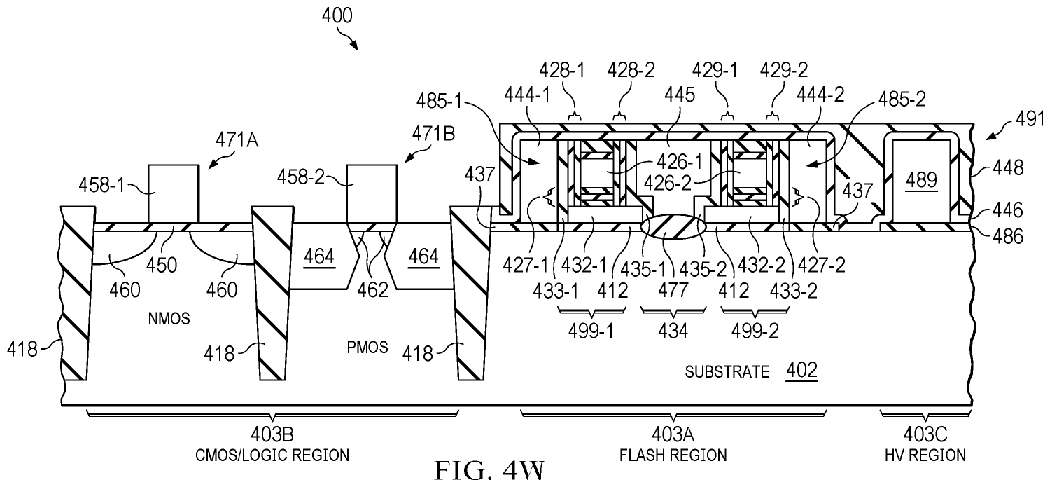

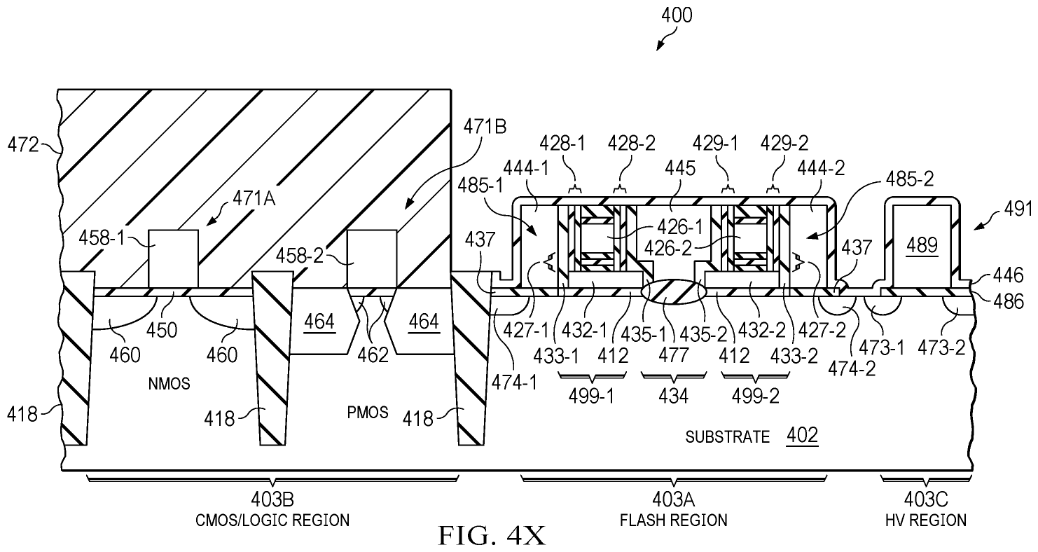

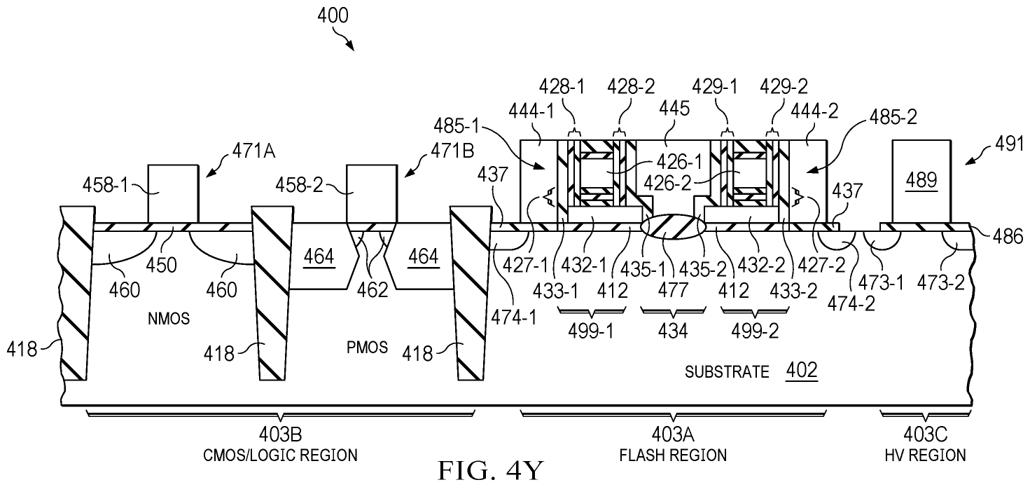

FIGS. 3A and 3B are flowcharts of an IC fabrication method according to some examples of the present disclosure. FIGS. 4A-4Y depict cross-sectional views of various stages of a modularizable process flow for fabricating an IC having Flash memory, CMOS logic circuitry, or both, according to some examples of the present disclosure. Turning first to FIGS. 4A-4Y, reference number 400 therein generally refers to a partially formed IC device 400 fabricated in a semiconductor die or a portion thereof provided as part of a suitable semiconductor wafer, where a substrate 402 may include a region or area 403A (which may be an example of or include aspects of the area 102A) for forming Flash memory cells therein, a region or area 403B (which may be an example of or include aspects of the area 102B) for forming CMOS logic circuitry including one or more LV domains, and a region or area 403C (which may be an example of or include aspects of the area 102A) for forming one or more HV domains associated with the Flash memory cells, as noted previously in reference to the example depicted in FIG. 1.

Although numerous examples of CMOS logic circuitry have been described in reference to FIG. 1, the fabrication of an IC according to the teachings herein may involve any combination or sub-combination of such example circuits, without necessarily being limited thereto or requiring any particular Flash memory array arrangement, embedded or otherwise. For instance, an IC device according to the teachings herein may comprise a standalone Flash memory device including an array of memory cells formed in a region (which may also be referred to as a Flash region, bitcell region, memory cell region, or in terms of similar import) and associated HV domain circuitry including HV devices (e.g., operating at 4.0V or higher, without limitation) formed in a region (which may also be referred to as an HV region, a first voltage region, or in terms of similar import).

In some arrangements, an example IC device may comprise a CMOS-only device where one or more CMOS logic circuits formed in a region (which may also be referred to as a CMOS region, logic region, a second voltage region, or in terms of similar import) may be disposed in one or more voltage domains comprising LV transistors operable at different operational voltages depending on implementation, application, and/or technology node involved, e.g., 1.0V, 1.5V, 1.8V, 3.3V, etc., without limitation, as well as any HV devices not dedicated to Flash memory operations. In some arrangements, an example IC device may comprise Flash memory formed in a Flash region, Flash-associated HV domain circuitry formed in an HV region and CMOS logic circuitry formed in a CMOS region.

Depending on the context and the level of functional integration, an example IC 400 may therefore include one or more combinations of the foregoing regions, where a Flash region (e.g., region 403A) may be referred to as a first region, a CMOS logic region (e.g., region 403B) may be referred to as a second region, and an HV region (e.g., region 403C) may be refereed to as a third region. Further, because the fabrication of Flash cells is integrated together with the fabrication of associated HV devices in a modularized Flash First flow, the regions 403A and 403C may also be commonly referred to as a first region in some examples unless specifically identified or distinguished otherwise.

FIG. 4A depicts the IC device 400 in an early fabrication stage where a pad oxide layer 404 of suitable thickness is formed over the substrate 402. Thereafter, a nitride layer 406 of suitable thickness is formed over the pad oxide layer 404 in preparation for a photolithography and etch stage configured to define the Flash region 403A and corresponding HV region 403C in the substrate 402. In one arrangement, a total thickness of the pad oxide layer 404 and the nitride layer 406 may be about 300 Å to 2000 Å, without limitation. The formation of various layers such as the pad oxide layer 404 and nitride layer 406 as well as other dielectric layers, conductive layers, non-conductive layers, etc., set forth herein may be performed using a variety of techniques, materials and in different thicknesses. The substrate 402 may predominantly comprise suitably doped silicon in some examples, although other semiconductor materials such as, Ge, GaAs, SiC, GaN, other Group III-V materials, etc., may be used in some implementations, where one or more epitaxial layers or single-crystal layers may be formed or provided in certain areas of the substrate 402 in some arrangements.

FIG. 4B depicts a patterned photomask 408 formed over the nitride layer 406 for defining Flash and HV regions 403A, 403C, while covering the CMOS/logic region 403B of the substrate 402. Depending on implementation, suitable etch process(es) may be deployed for removing the mask material, nitride material and pad oxide material uncovered by the patterned photomask 408. Subsequently, an implant process may be performed in the Flash/HV regions 403A/403C with the patterned photomask 408 in place. In some examples, the implant process may include an anti-punch-through (APT) implant or well implant for the transistors associated with the bitcells. By way of illustration, a doped layer 410 may be formed by implanting dopants in the Flash region 403A (e.g., boron) and the HV region 403C (e.g., boron, phosphorus), respectively. Although FIG. 4B shows the patterned photomask 408 uncovering both the Flash region 403A and the HV region 403C for illustration purposes, in some examples, more than one patterned photomasks may be used to implant appropriate dopants in the Flash region 403A and the HV region 403C with the CMOS/logic region 403B covered. In some examples, the patterned photomask 408 may expose the Flash region 403A while covering the HV region 403C and the CMOS/logic region 403B-e.g., in view of appropriate implants for the HV region 403C performed with the patterned photomask 484 described with reference to FIG. 4K.

In some examples, subsequent processing may involve removal of the photomask layer 408 from the CMOS/logic region 403B and oxidation of the exposed substrate in the Flash and HV regions 403A, 403C, respectively, such that a “pristine” surface may be provided therein for the formation of Flash bitcells as well as associated HV devices. Depending on implementation, such processes may involve a local oxidation of silicon (LOCOS) process, or an etch process (e.g., dry etch) followed by an oxidation step, which may be configured to clean and condition the surface of the substrate material in the Flash and HV regions 403A, 403C so that any dislocations and/or impurities that might have been caused by the etch process may be removed therefrom.

Although a single Flash region 403A, a single CMOS logic region 403B and a single HV region 403C are exemplified herein, there is no specific requirement or limitation as to the number of Flash regions, CMOS logic regions, and/or HV regions that may be provided in an example implementation. Moreover, FIG. 4B (and FIGS. 4C-4Y) depicts a schematic illustration of one or more transition regions between the Flash region 403A and the CMOS logic region 403B and/or between the Flash region 403A and the HV region 403C so as to juxtapose the regions side-by-side, where details of the transition regions depicted in these Figures may deviate from actual structural configurations of the transition region(s), which may vary based on details of integration schemes for fabricating Flash memory and CMOS logic circuitry. Further, although the Flash region 403A and the HV region 403C are sometimes referred to as “first region” and “third region”, respectively, they may be treated as a single region, e.g., a “first region”, relative to the CMOS logic region 403B, at least in some examples with respect to some of the processing steps of a Flash First flow as previously noted. Still further, where a Flash-only or a CMOS-only product fabrication is contemplated in a modularized flow, an example semiconductor substrate 402 may not include such specifically segregated regions therein.

Referring to FIG. 4C, a floating gate (FG) oxide layer 412 (which may include aspects of the gate oxide 218A) and an FG layer 414 (which may include aspects of the floating gate 216A) comprising polysilicon may be formed over the regions 403A-403C of the substrate 402 after removing the nitride layer 406 and the pad oxide layer 404. Also, a hard mask layer 416 comprising oxide material may be formed over the FG layer 414. The hard mask layer 416 may facilitate forming the field isolation described below with reference to FIG. 4D.

As will be seen further below, whereas respective portions of the FG oxide layer 412 and the FG layer 414 in the first region 403A may be processed as part of the Flash First fabrication flow for forming the floating gates and FG oxide components of the bitcell gate stacks of a Flash array, the FG oxide layer and FG layer portions in the second region 403B and the third region 403C may remain substantially unaltered until the formation of the bitcell gate stacks in the first region 403A is completed. Thereafter, the FG oxide layer and the FG layer portions of the third region 403C may be removed for facilitating the fabrication of HV transistors therein, which takes place along with the formation of wordline transistors coupled to the bitcell gate stacks in the first region 403A as an additional part of the Flash First flow for facilitating the modularization of Flash bitcell and HV device fabrication. Where the integration of CMOS logic circuitry is also contemplated, the FG oxide layer and the FG layer portions of the second region 403B may be removed after fabricating the bitcells (comprising bitcell gate stacks and wordline transistors coupled thereto) in the Flash region 403A and associated HV devices in the HV region 403C in the Flash First phase of the flow and before forming appropriate transistor devices for the desired CMOS logic circuitry in the second region 403B in a subsequent phase.

In an example implementation, the FG oxide layer 412 may be formed by a suitable process, e.g., deposited, oxidized or otherwise grown, and may have a thickness of about 50 Å to 150 Å, without limitation. In an example implementation, the polysilicon FG layer 414 may have a thickness of about 150 Å to 450 Å, without limitation.

Field isolation between various regions of the semiconductor substrate 402 as well as active area definitions in respective locations therein may be provided by a shallow trench isolation (STI) process, as illustrated in FIG. 4D. The STI process involves forming STI structures 418 at appropriate locations in the substrate 402 with respect to PMOS and NMOS areas of the second region 403B. The STI structures formed in the first region 403A with respect to the Flash bitcells are not specifically shown in the cross-sectional view of FIG. 4D because the Flash STI structures may be formed along a direction (along the X-axis) that is parallel to the cutting plane (i.e., not orthogonal to the cutting plane of the cross-sectional view). Also, the formation of STI structures relative to the HV region 403C is not specifically shown in FIG. 4D (and subsequent cross-sectional views of FIGS. 4E-4Y) for simplicity and clarity. An example STI process may involve STI mask photolithography, dry etch and clean, liner oxidation, STI filling and polishing (e.g., via chemical mechanical polishing or CMP) to generate the trench structures 418.

FIG. 4E depicts a process stage for forming an inter-gate oxide-nitride-oxide (ONO) layer 420 (which may include aspects of the inter-gate dielectric layer 214A) and a polysilicon control gate (CG) layer 422 (which may include aspects of the control gate 212A) over the regions 403A-403C of the substrate 402. A hard mask layer 424 comprising oxide-nitride material (e.g., a composite layer including at least an oxide layer and a nitride layer on top of the oxide layer) may be formed over the CG layer 422. In some examples, the ONO layer 420 may have a thickness of about 100 Å to 150 Å, without limitation. In some examples, the polysilicon CG layer 422 may have a thickness of about 300 Å to 600 Å, without limitation. Whereas an initial thickness of the hard mask layer 424 may be about 1500 Å to 2000 Å, it may be thinned to a suitable height depending on implementation.

FIG. 4F depicts a process stage where the gate stacks of a pair of adjacent bitcells are defined and respective gate spacers are formed in the Flash region 403A. As illustrated, gate stacks 485-1 and 485-2 with respect to bitcells 499-1 and 499-2 are formed over the FG layer 414 of the Flash region 403A, where reference numbers 427-1, 427-2 refer to respective inter-gate ONO dielectric components and reference numbers 426-1, 426-2 refer to respective CGs of the gate stacks 485-1 and 485-2 that are patterned from the ONO layer 420 and the polysilicon CG layer 422 shown in FIG. 4E. Because the components of a gate stack are also components of a bitcell, the terminology of bitcells and gate stacks may be used somewhat interchangeably with respect to some of the constituent components depending on the context unless otherwise expressly noted.

Continuing to refer to FIG. 4F and within the terminological equivalence framework set forth herein, spacers 428-1 and 428-2 (which may include aspects of the vertical spacer 230A) are formed along respective vertical sidewalls of CG 426-1 of the bitcell 499-1. The spacers may extend from the FG layer 414 to a top surface of a patterned hard mask component 423-1 (patterned from the hard mark layer 424 shown in FIG. 4E) overlying CG 426-1. In similar fashion, spacers 429-1 and 429-2 may be formed to cover respective vertical sidewalls of CG 426-2 of the bitcell 499-2 that may extend to the FG layer 414 and to a top surface of a patterned hard mask component 423-2 overlying CG 426-2. Depending on implementation, spacers 428-1/428-2 and 429-1/429-2 may each comprise one or more dielectric layers of suitable materials and thicknesses—e.g., a composite layer including at least an oxide layer and a nitride layer on the oxide layer. In some arrangements, the hard mask components 423-1 and 423-2 may be operable to protect the Flash bitcells 499-1 and 499-2 from subsequent processing steps in addition to acting as stop layers during the fabrication of wordline gates of the Flash bitcells 499-1 and 499-2, respectively. In some arrangements, respective sidewall spacers 428-1/428-2 and 429-1/429-2 may be selectively thinned or reduced to comply with applicable cell design rules.

FIG. 4G depicts a cell V_{T} definition stage where a wordline side of the CG is opened to remove a portion of the vertical sidewall (e.g., provided as an offset spacer component thereof) and facilitate a suitable V_{T} implant process with respect to the Flash bitcells. As illustrated, a photoresist layer 430 is patterned so as to expose the wordline sides of CGs 426-1 and 426-2 with respect to the bitcell pair 499-1/499-2.

FIG. 4H depicts that, after the cell V_{T} implant, a polysilicon etch is performed for defining and forming respective FIGS. 432-1 and 432-2 from the FG layer 414 with respect to the bitcell pair 499-1/499-2.

FIG. 4I depicts that, after forming FIGS. 432-1 and 432-2, an oxide spacer may be formed on each vertical side of FIGS. 432-1 and 432-2 so as to provide isolation. As illustrated in FIG. 4I, oxide spacers 433-1 may be formed on each side of FG 432-1 of the bitcell 499-1 and oxide spacers 433-2 may be formed on each side of FG 432-2 of the bitcell 499-2.

FIG. 4J depicts that an isolation structure 477 may be provided overlying a common source area 434 disposed between the bitcells 499-1 and 499-2. In some examples, the oxide spacers 433-1 and 433-2 facing the common source area 434 are selectively removed (e.g., using a photolithography exposing the oxide spacers 433-1 and 433-2). Moreover, the spacers 428-2 and 429-1 proximate the common source area 434 may be at least thinned (e.g., using a photolithography exposing the spacers 428-2 and 429-1). Also, an implant process may selectively introduce dopants into the common source area 434. After forming the isolation structure 477, vertical tunnel oxide sidewalls 435-1 and 435-2 can be formed. As shown in FIG. 4J, respective portions of the FG oxide layer 412 underlying FIGS. 432-1 and 432-2 may extend to the isolation structure 477. Further, the isolation structure 477 may extend to the vertical tunnel oxide sidewalls 435-1 and 435-2.

FIG. 4K depicts that a patterned mask 484 may be provided to cover the Flash region 403A and the CMOS/logic region 403B while exposing the HV region 403C so as to facilitate the removal of a portion of the FG oxide layer 412 overlying the HV region 403C. Further, a well implant 482 with appropriate dopant species (N-well or P-well) may be provided in the HV region 403C.

FIG. 4L depicts the stage after removing the mask 484 and forming the HV gate oxide layer 486 in the HV region 403C, which may be referred to as a first gate oxide layer in some examples. Depending on implementation, the HV gate oxide layer 486 may have a thickness of about 150 Å to about 200 Å and may be exclusive of nitridation.

In certain fabrication methods involving processing of Flash bitcells and CMOS logic in a staggered parallel fashion, e.g., going back and forth between Flash processing and CMOS logic processing until both circuit portions are completed substantially simultaneously, the gate oxide layer of HV devices formed along with gate oxide layers of the remaining transistors, e.g., LV domain devices, may be exposed to one or more nitridation process steps while the nitridation process steps provide nitridation for gate oxides for the CMOS logic transistors that may be disposed in multiple voltage domains. Whereas such nitridation of gate oxide layers (e.g., for the CMOS logic transistors) is commonly employed to help mitigate the deleterious effects of hot electron degradation caused in transistor devices operating under high energy fields, examples herein “decouple” the processing of Flash-dedicated HV transistors from CMOS logic processing in order to facilitate modularization of the flow such that the Flash-only devices, CMOS-only devices as well as Flash-and-CMOS devices may be fabricated on the same flow using different phases or “modules” of the flow without having to manage potential transistor mismatching issues.

In addition, gate oxides of wordline access transistors may also be fabricated in the Flash region 403A by way of a separate oxidation process as part of the Flash First phase, where the wordline gate oxides are also devoid of nitridation as will be set forth further below. In a subsequent phase involving the fabrication of CMOS logic circuitry in the second region 403B, where there is nitridation of gate oxides, the Flash bitcells as well as the HV devices are covered by a protective layer as described with reference to FIGS. 4R and 4S. In this manner, the gate oxides in access transistors (and other dielectric layers in the Flash bitcells) as well as the HV gate oxides are fabricated to be substantially free of nitridation (e.g., exclusive of nitridation).

In FIG. 4M, a wordline (WL) gate oxide mask 487 is shown that may be patterned for defining areas in the Flash region 403A where a WL gate oxide layer is to be formed with respect to the formation of WL gates (also referred to as access transistors or select transistors as previously noted) of the bitcells 499-1 and 499-2, respectively, while covering the CMOS/logic region 403B and the HV region 403C. As illustrated, the patterned WL gate oxide mask 487 exposes areas 479A and 479B adjacent to the bitcells 499-1 and 499-2, respectively, from which respective portions of the FG oxide layer 412 may be removed and a new oxide layer (also referred to as a third gate oxide layer in some examples) operable as WL gate oxide may be formed.

In FIG. 4N, a WL gate oxide layer 437 is formed in the exposed areas of the Flash region 403A, where the WL gate oxide layer 437 may have a thickness of about 15 Å to 35 Å and may comprise oxide material essentially devoid of nitridation similar to the HV gate oxide layer 486 being devoid of nitridation as noted above. After forming the WL gate oxide layer 437 in the Flash region 403A, a polysilicon layer 438 may be deposited, as illustrated in FIG. 4N, for facilitating the formation of WL gates and a common erase gate with respect to the bitcells 499-1 and 499-2 in the Flash region 403A as well as the formation of HV gates over the HV gate oxide 486 with respect to forming one or more HV devices in the HV region 403C.

FIG. 4O illustrates that the polysilicon layer 438 may be polished—e.g., utilizing a CMP process stopping on the hard mask layer 424 present in the second region 403B. Also, a portion of the polysilicon layer 438 in the first region 403A over the patterned hard mask components 423-1 and 423-2 may be removed—e.g., utilizing an etch-back process stopping on the patterned hard mask components 423-1 and 423-2. As a result, the polysilicon material over the second region 403B is removed and a thinned polysilicon layer 440 having a thickness of about 500 Å to 1500 Å may be provided, e.g., as a common gate layer, for forming WL gates and erase gate in the first region 403A and one or more HV gates in the third region 403C. In some examples, the common gate layer may have a thickness of about 300 Å to 1000 Å, without limitation.

FIG. 4P illustrates, after a suitable photolithography process, the formation of WL gates 444-1 and 444-2 as well as common erase gate 445 with respect to the bitcell pair 499-1 and 499-2, in addition to the formation of an HV gate 489 over the HV gate oxide layer 486 for operating as at least one HV device 491 (also referred to a first transistor operable at a first voltage level). As shown in FIG. 4P, WL gate 444-1 overlying a corresponding WL oxide portion 437 is provided as part of the bitcell 499-1, WL gate 444-2 overlying a corresponding WL oxide portion 437 is provided as part of the bitcell 499-2, and erase gate 445 is commonly associated with both bitcells 449-1 and 449-2, thus substantially corresponding to the structure of the bitcell pair 202A/202B described previously in reference to FIGS. 2A and 2B. Further, the WL oxide layer portion 437 extending between the Flash region 403A and the HV region 403C may be removed. After forming the WL gates 444-1 and 444-2, erase gate 445, and HV gate 489, a patterned photoresist or mask used in the gate definition photolithography process (and the hard mark layer 424 in the second region 403B) is removed.

After fabrication of the WL gates 444-1/444-2, common erase gate 445 and the HV gate 489, the formation of Flash bitcells 499-1/499-2 and associated HV device(s) 491 is substantially complete and the process flow may switch to forming CMOS logic circuitry according to some examples. In some arrangements, source/drain (S/D) extension regions (e.g., including lightly-doped drain (LDD) regions) may be formed (e.g., via suitable implantation techniques) with respect to the WL gates (e.g., WL gates 444-1/444-2) in the Flash region 403A and/or the HV device(s) 491 in the HV region 403C before commencing CMOS logic processing. In some additional and/or alternative arrangements, the formation of LDD extensions in the Flash region 403A and the HV region 403C may be postponed (as described with reference to FIG. 4X) until after substantially completing the CMOS logic circuitry in the second region 403B.

In some examples, the CMOS logic processing may start with forming a protective layer 475 including a nitride sublayer 446 and an oxide sublayer 448 over the Flash region 403A, the HV region 403C as well as the CMOS/logic region 403B for sealing and protecting the circuitry of the Flash region 403A and the HV region 403C during the formation of logic circuity (e.g., comprising one or more sets of transistors operable at corresponding second voltage levels) in the CMOS/logic region 403B. Subsequently, as shown in FIG. 4Q, the oxide sublayer 448 in the second region 403B may be removed—e.g., by utilizing a CMP process configured to stop on the nitride sublayer 446 in the second region 403B. In some arrangements, a portion of the oxide sublayer 448 may remain on the nitride sublayer 446 in the Flash region 403A and the HV region 403C—e.g., at the end of the CMP process. In this manner, the gate stacks 485-1/485-2, associated WL gates 444-1/444-2 and the common erase gate 445 of the circuitry of the Flash region 403A as well as the HV device(s) 491 are sealed and protected during the formation of CMOS logic circuity in the second region 403B.

In other words, the protective layer 475 may initially extend over the second region 403B, which may be polished using CMP to a suitable thickness depending on implementation such that only a portion of the protective layer 475 (e.g., the nitride sublayer 446) is remaining over the second region 403B. As illustrated in FIG. 4Q, the CMP process may involve removing the oxide sublayer 448 from the second region 403A while the nitride sublayer 446 of the protective layer 475 remains extended over a polysilicon layer formed in the second region or area 403B, e.g., the CG polysilicon layer portion 422 used for forming CG gates in the first region 403A during the earlier stages of the Flash First flow module described above. As such, the protective layer 475 may be polished such that a top surface of the protective layer 475 remaining in the first region 403A (e.g., the top surface of the remaining oxide sublayer 448 after CMP) and disposed over the Flash memory cells and associated gates does not present a steep vertical topology with respect to the nitride sublayer of the second area 403B.

Substantially completing the fabrication of Flash bitcells including the WL and erase gates associated therewith in a Flash First flow according to the teachings herein may be particularly advantageous over processing the CMOS logic circuitry before forming the Flash circuitry and/or substantially concurrently because the V_{T} settings configured for different CMOS devices having variable operational voltages will not be disturbed by the process steps (e.g., high-temperature processes) involved in a subsequent or substantially concurrent Flash circuitry process flow. Further, as the Flash bitcells and associated HV devices are formed first, independent from CMOS logic integration, they can be removed from a CMOS-only product flow, thereby allowing process modularization where products of a technology node having different functionalities and levels of integration may be fabricated using the same flow while avoiding potential transistor performance mismatch issues that may arise in certain process flows as previously noted.

FIG. 4R illustrates that various layers present above the FG oxide layer 412 are removed in the second region 403B. As shown in FIG. 4R (in comparison to FIG. 4Q), the nitride sublayer 446, the CG polysilicon layer portion 422, the inter-gate ONO layer 420, and the FG layer 414 remaining in the second region 403B are removed. The remaining oxide sublayer 448 in the Flash region 403A and the HV region 403C may be at least partially removed as shown in FIG. 4R (in comparison to FIG. 4Q) while the various layers present above the FG oxide layer 412 are removed in the second region 403B. Further, the FG oxide layer portion 412 remaining in the second region 403B may also be removed (not specifically shown in this Figure) in preparation for forming a logic gate oxide layer in a subsequent stage (e.g., gate oxide layer 450 illustrated in FIG. 4S), which may be referred to as a second gate oxide layer in some examples herein.

According to the examples herein, the second gate oxide layer 450 in the second region 403B may undergo a suitable nitridation process such that second gate oxide layer 450 can be more robust against hot electron degradation. Contrastingly, the WL gate oxide layer 437, the FG oxide layer 412 and the HV gate oxide layer 486 are not exposed to the nitridation process because of the various layers present thereover, respectively. By way of example, the WL gate oxide layer 437 is covered by the WL gates 444, the nitride sublayer 446, and the remaining oxide sublayer 448, thereby prevented from exposure to nitridation. Likewise, the FG oxide layer 412 is covered by the gate stacks 485-1/485-2 and the HV gate oxide layer 486 is covered by the HV gate 489, both of which are covered by the nitride sublayer 446 and the remaining oxide sublayer 448, thus protected from nitridation of the second gate oxide layer 450. Accordingly, the WL gate oxide layer 437 as well as the FG oxide layer 412 and the HV gate oxide layer 486 are remain exclusive of the nitridation.

Further, although FIG. 4S depicts one second gate oxide layer 450 in the second region 403B, the second region 403B may include more than one gate oxide layers having different thicknesses in different areas. For example, the second gate oxide layer 450 may be processed to have a range of thicknesses in different areas of the second region 403B, e.g., ranging from about 15 Å to about 200 Å, for facilitating the manufacture of transistors having different respective operational voltage levels, e.g., 1.0V, 1.5V, 1.8V, 3.3V, etc., as previously set forth. In general, logic transistors having higher operational voltages may be provided with a thicker gate oxide layer, whereas logic transistors having lower operational voltages may be formed with a thinner gate oxide layer. Regardless of the thickness of the different instances of the second gate oxide layer 450, it may be nitridated for NMOS devices, PMOS devices, or both, that form the CMOS logic circuitry, in order to reduce hot electron degradation that may be caused by high energy fields during their electrical operation as previously noted.

Continuing to refer to FIG. 4S, a logic polysilicon layer 452 may be formed over the second gate oxide layer 450 in the second region 403B, which may extend over the remaining oxide sublayer 448 of the protective layer 475 in the Flash region 403A and the HV region 403C. In some examples, the logic polysilicon layer 452 may have a thickness of about 600 Å to 800 Å, without limitation.

FIG. 4T illustrates that a hard mask 454 comprising nitride material having a thickness of about 400 Å to 500 Å and a diamond-like carbon (DLC) hard mask 456 having a thickness of about 800 Å to 1000 Å are formed over the logic polysilicon layer 452. The hard mask 454 comprising nitride material and the DLC hard mask 456 facilitate logic gate patterning for high performance transistors. For example, a gate mask arrangement (not specifically shown) may be utilized in a suitable photolithography process for forming logic gates of appropriate lengths, e.g., 28 nanometers (nm), 34 nm, 36 nm, etc., in the second region 403B as illustrated in FIG. 4U.

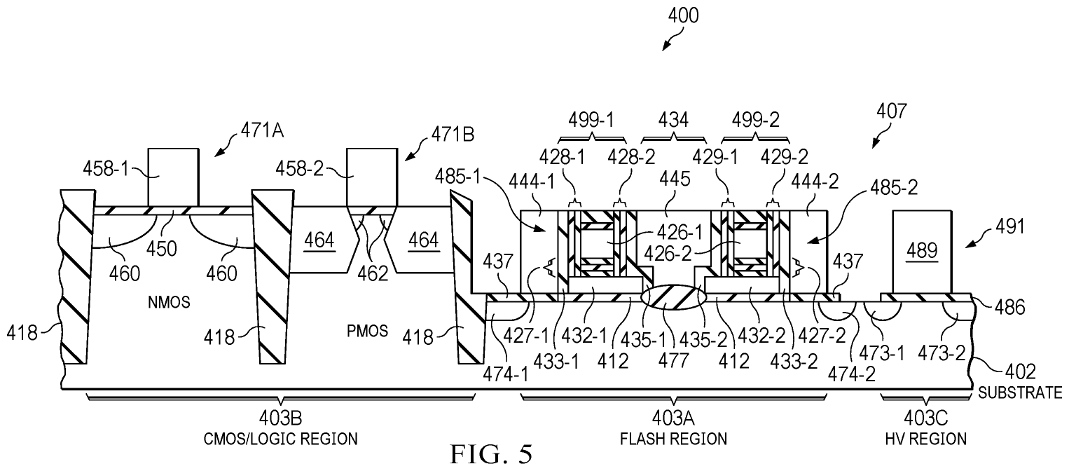

In the arrangement illustrated in FIG. 4U, an NMOS device 471A including a gate 458-1 and a PMOS device 471B including a gate 458-2 are exemplified as CMOS logic devices in the second region 403B. Further, appropriate S/D extensions 460 and 462 (which may also be referred to as LDD regions) may be provided for the NMOS and PMOS devices 471A, 471B, respectively, as illustrated in FIG. 4V. In some examples, an embedded silicon-germanium (SiGe) layer 464 may be provided in PMOS device(s) 471B, as illustrated in FIG. 4W, for providing compressive stress in the channel region, which improves the PMOS device performance. In some arrangements involving the formation of an embedded SiGe layer, the hard mask 454 may be removed at the end of SiGe formation, as set forth in FIG. 4W as well as FIGS. 4X-4Y and FIG. 5 described below.

After fabricating the CMOS devices 471A, 471B including S/D extensions (e.g., LDD regions) therein, and depending on optional SiGe layer formation for the PMOS devices, an example process flow with respect to logic circuitry processing in the second region 403B is substantially completed and the flow may switch to further processing of Flash circuitry in some arrangements. In one example, LDD processing of the WL transistors formed in the Flash region 403A and LDD processing of the HV transistors formed in the HV region 403C may be effectuated at this juncture as illustrated in FIG. 4X, where a patterned photoresist 472 may be provided to cover the CMOS logic circuitry of the second region 403B while exposing the first and third regions 403A, 403C, respectively. A suitable etch process (e.g., a wet HF etch) may be deployed to remove the remaining oxide sublayer 448 (and the nitride sublayer 446 of the protective layer 475 in some examples) from the first and third regions 403A, 403C prior to Flash/HV LDD processing in some examples. Appropriate LDD extensions 474-1, 474-2 may be formed with respect to WL gates 444-1/444-2, e.g., via suitable implant techniques. Likewise, appropriate LDD extensions 473-1, 473-2 may be formed with respect to HV gate(s) 489, e.g., via suitable implant techniques.

Subsequently, the patterned photoresist 472 covering the second region 403B as well as the remaining nitride sublayer 446 (if not removed prior to the LDD processing) over the Flash bitcells 499-1/499-2 and associated HV device(s) 491 may be removed, as illustrated in FIG. 4Y, whereupon the process flow may continue with suitable spacer formation, source/drain region formation, silicide formation process, PMD deposition process, contact formation and subsequent metallization processes according to applicable process stages depending on implementation. In some examples, the WL gates 444, the common erase gate 445 of the Flash bitcells 499 and/or HV gate(s) 489 may include a silicide layer (a silicide layer including tungsten, cobalt, or nickel, etc.) as a result of the silicide formation process.

Turning to FIGS. 3A and 3A, each depicting a portion 300A, 300B, respectively, a flowchart of an IC fabrication method is set forth therein according to some examples of the present disclosure, where the depicted steps, blocks, acts and/or functions of the flowchart portions may be combined and/or rearranged in various ways. At block 302, a plurality of Flash memory cell gate stacks may be formed in a first region of a semiconductor substrate, where each pair of adjacent Flash memory cells are configured to share a common erase gate. A plurality of first transistors operable at a first voltage level (e.g., greater than or equal to 4.0V in some implementations) may be formed in the first region, where a first transistor includes a gate formed over a first gate oxide layer exclusive of nitridation (block 304). At block 306, one or more sets of second transistors may be formed in a second region of the semiconductor substrate, where each set of second transistors is operable at a corresponding second voltage level different than the first voltage level and includes a corresponding second gate oxide layer having nitridation.

In an example arrangement, WL/access transistors coupled to the gate stacks of the Flash memory cells may be formed in the first region, each WL/access transistor including a WL/access gate formed over a third gate oxide layer. After forming the Flash memory cells including the gate stacks, common erase gates and WL/access transistors as well as the first transistors in the first region, a protective layer (e.g., comprising nitride-oxide material) may be formed over the first region (block 322), where a nitride sublayer of the protective layer extends over a polysilicon layer formed in the second region. In some arrangements, the nitride sublayer and the polysilicon layer may be removed from the second region prior to forming the second transistors in the second region (block 324), with a remaining portion of the protective layer covering the Flash memory cells and the first transistors in the first region. After forming the second transistors in the second region, the remaining portion of the protective layer may be removed from the first region (block 326). In some arrangements, a patterned photoresist may be formed over the second region while exposing the first region, whereupon suitable doped extension regions may be formed relative to respective access gates and the first transistors in the first region, as set forth at blocks 328 and 330.

In some additional and/or alternative arrangements, one or more recessed areas may be formed in the first region, where the Flash cells may be formed in a first recessed area and the first transistors may be formed in a second recessed area different than the first recessed area, e.g., as set forth below in reference to FIG. 5. In this manner, the challenges of having to manage different vertical topographies with respect to the logic circuitry and Flash memory due to the presence of a floating gate in the memory cells may be mitigated. In certain process flows where CMOS logic and Flash memory portions are fabricated on a common substrate, logic gate definition continues to be a highly demanding task when the cell gate stacks are already defined, thereby presenting a steep step height during the processing of CMOS logic gates. Because of the significant disparities in the aspect ratios between the Flash array features and logic circuitry structures, various processing stages tend to become highly susceptible to errors, thereby impacting the overall die yield, especially in advanced technology nodes that continue to scale to smaller geometries.

Some additional and/or alternative examples of the present disclosure appreciate the foregoing challenges and may therefore be modified to account for the aspect ratio differences where the Flash memory cells and associated HV transistors dedicated to Flash operations (e.g., first transistors) may be processed and substantially completed in one or more recessed areas of the semiconductor substrate (e.g., forming a first region) as part of the modularized Flash First flow described above in detail. For example, prior to forming the doped layer 410 described with reference to FIG. 4B, the Flash and HV regions 403A, 403C may be recessed with respect to the the CMOS/logic region 403B such that the Flash memory cells and associated HV transistors dedicated to Flash operations (e.g., first transistors) may be disposed in one or more recessed areas of the semiconductor substrate. Subsequently, the logic circuitry (e.g., comprising one or more sets of second transistors) may be fabricated in a non-recessed area of the semiconductor substrate (e.g., forming a second region). In some arrangements, the depth of recessed areas may be about 1000 Å to 1200 Å from a gate oxide layer formed in the non-recessed area for the one or more sets of the second transistors that may be operable at different voltages than the operating voltages of the first transistors as noted above.

In some arrangements, the recessed area may be optimized such that the gate oxide layer formed in the non-recessed area for the logic circuitry (e.g., the second gate oxide layer) may be substantially coplanar with respect to a top surface of the Flash memory cells, thereby reducing aspect ratio disparities that would otherwise be prevalent in certain process flows. By way of illustration, Flash region 403A and HV region 403C are located in a recessed area 407 of the substrate 402 relative to the CMOS logic region 403B (which may be formed in a non-recessed area) as shown in FIG. 5, where like components are denoted with the same reference number or initialism as corresponding components the cross-sectional view of FIG. 4Y described in detail hereinabove. In some arrangements, Flash region 403A and HV region 403C may be located in different recessed areas of the substrate 402. In an example implementation, the gate oxide layer formed in the non-recessed area for the logic circuitry (e.g., the second gate oxide layer 450) may be substantially coplanar with respect to a top surface of the HV transistors 491. Additional details regarding a Flash First flow involving recessed substrate areas may be found in U.S. patent application Ser. No. 18/362,080 (Docket No. T102799US01) filed Jul. 31, 2023, which is incorporated by reference herein for all purposes.

Although some example implementations may involve NMOS-based split-gate Flash memory bitcells, the teachings herein are not limited thereto. Some example implementations may include PMOS-based Flash memory bitcells or non-split gate bitcell configurations in additional and/or alternative arrangements. Whereas various S/D implants, extension region implants (e.g., LDD implants) as well as additional implants such as halo/pocket implants, and the like may be used in some examples, not all such types of implants are required. Accordingly, a variety of bitline/drain implant profiles may be implemented where LDDs and/or halo/pocket implants are not necessary or may be optionally provided. Further, example implementations may involve various Flash architectures, e.g., single-level cell (SLC) Flash architectures (storing one bit of data per cell), multi-level cell (MLC) Flash architectures (storing more than one bit per cell), NAND-based Flash architectures, NOR-based Flash architectures, charge trap Flash architectures etc., as well as other types of NVM architectures.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a substrate including a first region and a second region;
a Flash memory cell gate stack formed in the first region;
a first transistor formed in the first region and operable at a first voltage level, the first transistor including a gate formed over a first gate oxide layer exclusive of nitridation; and
one or more sets of second transistors formed in the second region, each set operable at a corresponding second voltage level different than the first voltage level and including a corresponding second gate oxide layer having nitridation.

2. The IC as recited in claim 1, wherein the first gate oxide layer has a thickness of about 160 Å to 200 Å.

3. The IC as recited in claim 1, wherein the second gate oxide layer has a thickness ranging from about 15 Å to about 45 Å based on the second voltage level.

4. The IC as recited in claim 1, further comprising a wordline (WL) transistor formed in the first region and coupled to the Flash memory cell gate stack, the WL transistor including a WL gate formed over a third gate oxide layer exclusive of nitridation.

5. The IC as recited in claim 4, wherein the gate of the first transistor and the WL gate of the WL transistor are formed from a common gate layer.

6. The IC as recited in claim 5, wherein the common gate layer has a thickness of about 300 Å to 1000 521 .

7. The IC as recited in claim 4, wherein the third gate oxide layer has a thickness of about 15 Å to 35 Å.

8. The IC as recited in claim 1, wherein the each set of the second transistors includes a gate having a thickness of about 600 Å that overlies the second gate oxide layer.

9. The IC as recited in claim 8, the gate of the first transistor and the gate of the second transistors are formed from different gate layers.

10. The IC as recited in claim 1, wherein the first region comprises a recessed area having a depth of about 1000 Å to 1200 Å from the second gate oxide layers, and wherein the Flash memory cell gate stack and the first transistor are formed in the recessed area.

11. The IC as recited in claim 1, wherein:
the first region comprises a first recessed area and a second recessed area different than the first recessed area, the first and second recessed areas having a depth of about 1000 Å to 1200 Å from the second gate oxide layers;
the Flash memory cell gate stack is located in the first recessed area; and
the first transistor is located in the second recessed area.

12. The IC as recited in claim 11, wherein a top surface of the Flash memory cell is substantially coplanar with the second gate oxide layer.

13. The IC as recited in claim 11, wherein a top surface of the first transistor is substantially coplanar with the second gate oxide layers.

14. The IC as recited in claim 1, wherein:
the first voltage level is greater than or equal to 4V, such as 5V; and
the second voltage levels are less than 4V, such as 3.3V, 1.8V, 1.5V, or 1.0V.

15. The IC as recited in claim 1, wherein at least one set of the one or more sets of second transistors includes a silicon-germanium (SiGe) layer.

16. A method of fabricating an integrated circuit (IC), comprising:
forming a Flash memory cell gate stack in a first region of a substrate;
forming a first transistor operable at a first voltage level in the first region, the first transistor including a gate formed over a first gate oxide layer exclusive of nitridation; and
forming one or more sets of second transistors in the second region, each set operable at a corresponding second voltage level different than the first voltage level and including a corresponding second gate oxide layer having nitridation.

17. The method as recited in claim 16, wherein the first gate oxide layer has a thickness of about 160 Å to 200 Å.

18. The method as recited in claim 16, wherein the second gate oxide layer has a thickness ranging from about 15 Å to about 45 Å based on the corresponding second voltage level.

19. The method as recited in claim 16, further comprising forming a wordline (WL) transistor in the first region coupled to the Flash memory cell gate stack, the WL transistor including a WL gate formed over a third gate oxide layer exclusive of nitridation.

20. The method as recited in claim 19, wherein the gate of the first transistor and the WL gate of the WL transistor are formed from a common gate layer.

21. The method as recited in claim 20, wherein the common gate layer has a thickness of about 300 Å to 1000 Å.

22. The method as recited in claim 19, wherein the third gate oxide layer has a thickness of about 15 Å to 35 Å.

23. The method as recited in claim 19, wherein the Flash memory cell gate stack is adjacent to another Flash memory cell gate stack with a common erase gate between the Flash memory cell gate stacks.

24. The method as recited in claim 23, wherein the Flash memory cell gate stacks, the common erase gate, the first transistor and the WL transistor are formed in the first region before forming the one or more sets of second transistors in the second region.

25. The method as recited in claim 20, further comprising depositing a protecting layer over the Flash memory cell gate stacks, the common erase gate, the first transistor and the WL transistor, wherein a nitride sublayer of the protective layer extends over a polysilicon layer formed in the second region.

26. The method as recited in claim 25, further comprising:
removing the nitride sublayer and the polysilicon layer from the second region;
forming the one or more sets of second transistors in the second region, with a remaining portion of the protective layer covering the Flash memory cell gate stacks, the common erase gate, the first transistor and the WL transistor in the first region; and
removing the removing portion of the protective layer from the first region after forming the one or more sets of second transistors in the second region.

27. The method as recited in claim 16, wherein the first region comprises a recessed area having a depth of about 1000 Å to 1200 Å from the second gate oxide layers in the second region, wherein the Flash memory cell gate stack and the first transistor are formed in the recessed area.

28. The method as recited in claim 16, wherein the first region comprises a first recessed area and a second recessed area different than the first area, the first and second recessed areas having a depth of about 1000 Å to 1200 Å from the second gate oxide layers, wherein the Flash memory cell gate stack is located in the first recessed area and the first transistor is located in the second recessed area.

29. The method as recited in claim 28, wherein a top surface of the Flash memory cell is substantially coplanar with the second gate oxide layers.

30. The method as recited in claim 28, wherein a top surface of the first transistor is substantially coplanar with the second gate oxide layers.

31. The method as recited in claim 16, wherein at least one second transistor includes a silicon-germanium (SiGe) layer.
